(19) United States
(12) Patent Application Publication
(10) Pub. No.: US 2026/0013302 A1
(43) Pub. Date: Jan. 8, 2026

(54) Display Panel and Display Device Comprising the Same

(71) Applicant: LG Display Co., Ltd., Seoul (KR)

(72) Inventors: Seong Ho Ahn, Paju-si (KR); Dong Kwan Hyun, Paju-si (KR); Hyoung Sun Park, Paju-si (KR); Hyun Seok Na, Paju-si (KR)

(21) Appl. No.: 19/215,015

(22) Filed: May 21, 2025

(30) Foreign Application Priority Data
Jul. 8, 2024 (KR) 10-2024-0089734

(51) Int. Cl. H10H 29/80; H10H 29/37

(52) U.S. Cl. CPC H10H 29/842; H10H 29/37

(57) ABSTRACT

The present specification discloses a display panel and a display device including the same. The display panel may include: an insulating layer arranged on a substrate; a bank and a contact electrode arranged to be spaced apart from each other on the insulating layer; a first electrode arranged on the bank; a passivation layer including a first hole exposing an upper surface of the contact electrode and a second hole exposing an upper surface of the first electrode; a light-emitting element arranged on the first electrode; a second electrode arranged on the light-emitting element; a first optical layer surrounding the light-emitting element; and a second optical layer arranged on a side of the first optical layer, wherein the second electrode may come into contact with the upper surface of the contact electrode through a contact hole formed in the second optical layer and the first hole of the passivation layer.

### CROSS-REFERENCE TO RELATED APPLICATION

This application claims priority to and the benefit of Republic of Korea Patent Application No. 10-2024-0089734 filed on Jul. 8, 2024, which is hereby incorporated by reference in its entirety.

### FIELD

The present disclosure relates to an apparatus and particularly to, for example, without limitation, a display panel and a display device including the same.

### DISCUSSION OF RELATED ART

Display devices are applied to various electronic devices such as a television (TV), a mobile phone, a laptop, and a tablet.

The display devices include an organic light emitting display (OLED) that is self-emissive, a liquid crystal display (LCD) that requires a separate light source, and the like.

Recently, a display device including a light-emitting element (e.g., a light-emitting diode; LED) has been attracting attention as a next-generation display device. Since the light-emitting element is formed of an inorganic material rather than an organic material, the light-emitting element has a faster lighting speed, superior luminous efficiency, and can display an image with high luminance compared to the LCD or the OLED.

Micro LEDs may be used as light-emitting elements, and micro LEDs may be used as pixels of a display device. Micro LEDs may be inorganic LEDs with a size of 100 μm or less. Micro LEDs may be manufactured through a separate semiconductor process and may be transferred to the pixel positions of a display device.

### SUMMARY

Due to weakening of the adhesion between a contact electrode made of a metal material and a second optical layer made of an organic material placed in contact with the contact electrode, delamination may occur in the region where the contact electrode and the second optical layer come into contact. For example, this delamination phenomenon may occur in the region where the inner end of the second optical layer forming a contact hole meets the contact electrode. Here, the contact hole formed in the second optical layer is a structure provided to electrically connect the cathode electrode to the contact electrode.

During the process of depositing the cathode electrode, a disconnection defect of the cathode electrode may occur due to a delamination phenomenon in the region where the inner end of the second optical layer and the contact electrode meet, and such a disconnection defect of the cathode electrode may reduce the reliability of the display device.

Accordingly, there is a need for a display panel that may improve reliability in the manufacturing process and a display device including the same.

The problem to be solved by embodiments of the present specification is to provide a display panel with improved reliability in quality through strengthened adhesion between the contact electrode and the second optical layer, and a display device including the same.

An embodiment according to the present specification provides a display panel that prevents or reduces a disconnection defect of the cathode electrode by arranging a passivation layer of an inorganic insulating material between the contact electrode and the second optical layer made of different materials, and a display device including the same.

An embodiment according to the present specification provides a display panel that prevents or reduces damage to the exposed conductive layer in advance through a passivation layer of an inorganic material, and a display device including the same.

An embodiment according to the present specification provides a display panel that presents various arrangement structures in terms of reliability for a light-emitting element, an electrode located below the light-emitting element, a solder pattern connecting the light-emitting element and the electrode, and a passivation layer, and a display device including the same.

It should be noted that objects of the present disclosure are not limited to the above-described objects, and other objects of the present disclosure will be apparent to those skilled in the art from the following descriptions.

A display panel according to an embodiment of the present specification may include: an insulating layer arranged on a substrate; a bank and a contact electrode arranged to be spaced apart from each other on the insulating layer; a first electrode arranged on the bank; a passivation layer including a first hole exposing an upper surface of the contact electrode and a second hole exposing an upper surface of the first electrode; a light-emitting element arranged on the first electrode; a second electrode arranged on the light-emitting element; a first optical layer surrounding the light-emitting element; and a second optical layer arranged on a side of the first optical layer, wherein the second electrode may come into contact with the upper surface of the contact electrode through a contact hole formed in the second optical layer and the first hole of the passivation layer.

A display device according to an embodiment of the present specification may include: a display panel; a polarizing layer arranged on the display panel; a printed circuit board; and a flexible circuit board electrically connecting the display panel and the printed circuit board, wherein the display panel may include an insulating layer arranged on a substrate, a bank and a contact electrode arranged to be spaced apart from each other on the insulating layer, a first electrode arranged on the bank, a passivation layer including a first hole exposing an upper surface of the contact electrode and a second hole exposing an upper surface of the first electrode, a light-emitting element arranged on the first electrode, a second electrode arranged on the light-emitting element, a first optical layer surrounding the light-emitting element, and a second optical layer arranged on the side of the first optical layer, and wherein the second electrode may come into contact with the upper surface of the contact electrode through a contact hole formed in the second optical layer and the first hole of the passivation layer.

According to the present specification, by arranging a passivation layer of an inorganic insulating material between a contact electrode of a metal material and a second optical layer of an organic insulating material, delamination may be prevented or reduced from occurring in the region where the inner end of the second optical layer and the contact electrode meet. Hence, in the process of depositing the cathode electrode, a disconnection defect of the cathode electrode due to a delamination phenomenon can be prevented or reduced, thereby improving the reliability of the display panel and the display device including the same. Accordingly, the possibility of defective lighting of the light-emitting element due to a disconnection defect of the cathode electrode may be blocked in advance.

According to the present specification, process optimization through a passivation layer of an inorganic insulating material used to prevent or reduce a disconnection defect of the cathode electrode may minimize or reduce defects of the display panel. Hence, greenhouse gas emissions may be reduced in terms of the production process of display devices.

The effects of this specification are not limited to the effects mentioned above, and other effects not mentioned will be clearly understood by those skilled in the art to which the technical idea of this specification pertains from the following description.

It is to be understood that both the foregoing general description and the following detailed description are exemplary and explanatory and are intended to provide further explanation of the inventive concepts as claimed.

### BRIEF DESCRIPTION OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is an exploded perspective view illustrating a display device according to an embodiment of the present specification;

FIG. 2 is a plan view illustrating the display device according to an embodiment of the present specification;

FIG. 3 is an enlarged view illustrating the display device according to an embodiment of the present specification;

FIG. 4 is a diagram illustrating a circuit structure according to an embodiment of the present specification;

FIG. 5 is a plan view illustrating the display device according to an embodiment of the present specification;

FIG. 6 is a plan view illustrating the display device according to an embodiment of the present specification;

FIG. 7 is a plan view illustrating the display device according to an embodiment of the present specification;

FIGS. 8A and 8B are cross-sectional views illustrating the display device according to an embodiment of the present specification;

FIG. 9 is a cross-sectional view illustrating the display device according to an embodiment of the present specification;

FIG. 10 is a cross-sectional view of the display device according to an embodiment of the present specification;

FIG. 11 is a cross-sectional view of the display device according to an embodiment of the present specification;

FIG. 12 is a view illustrating a first electrode of the display device according to an embodiment of the present specification;

FIG. 13 is a view illustrating a contact electrode of the display device according to an embodiment of the present specification;

FIG. 14 is a view illustrating the arrangement relationship between the first electrode and a passivation layer of the display device according to an embodiment of the present specification;

FIG. 15 is a view illustrating the arrangement relationship between the contact electrode and the passivation layer of the display device according to an embodiment of the present specification;

FIG. 16 is a view illustrating the arrangement relationship between the contact electrode, the passivation layer, and a second optical layer of the display device according to an embodiment of the present specification;

FIG. 17 is a view illustrating a comparative example;

FIGS. 18A to 18J are views illustrating a process of forming first electrode, contact electrode, passivation layer, solder pattern, light-emitting element, first optical layer, second optical layer, and second electrode of the display device according to an embodiment of the present specification;

FIG. 19 is a cross-sectional view of a display device according to another embodiment of the present specification; and

FIGS. 20 to 23 are diagrams illustrating apparatuses to which display devices according to embodiments of the present specification are applied.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

The advantages and features of the present disclosure and methods for accomplishing the same will be more clearly understood from embodiments described below with reference to the accompanying drawings. However, the present disclosure is not limited to the following embodiments but may be implemented in various different forms. Rather, the present embodiments will make the disclosure of the present disclosure complete and allow those skilled in the art to completely comprehend the scope of the present disclosure. The present disclosure is only defined within the scope of the accompanying claims.

Any implementation described herein as an “example” is not necessarily to be construed as preferred or advantageous over other implementations.

Shapes, sizes, ratios, angles, numbers, and the like disclosed in the drawings for describing the embodiments of the present disclosure are exemplary, and the present disclosure is not limited to the illustrated items. Like reference numerals refer to like elements throughout. In addition, in describing the present disclosure, if it is determined that the detailed description of the related known technology may unnecessarily obscure the subject matter of the present disclosure, the detailed description thereof will be omitted.

The terms such as “comprising”, “including”, and “having” used herein are generally intended to allow other components to be added unless the terms are used with the term “only”. References to the singular shall be construed to include the plural unless expressly stated otherwise.

In interpreting a component, it is interpreted to include an error range even if there is no separate description.

In the case of a description of a positional relationship, for example, when the positional relationship of two parts is described as ‘on,’ ‘at an upper portion,’ ‘at a lower portion,’ ‘next to, and the like, one or more other parts may be located between the two parts unless ‘immediately’ or ‘directly’ is used.

When describing a temporal contextual relationship is described, such as “after,” “following,” “next to,” or “before,” it may also include non-contiguous cases unless “immediately” or “directly” is used.

In the description for the embodiments, the first, second, etc. are used to describe various components, but these components are not limited by these terms. These terms are only used to distinguish one component from another. Therefore, the first component mentioned below may be a second component within the technical idea of the present disclosure.

Terms such as first, second, A, B, (a), (b), and the like may be used to describe elements of the embodiments of the present specification. Such terms are intended only to distinguish one component from another and are not intended to define the nature, sequence, order, or number of such components.

When a component is described as “connected,” “coupled,” or “attached” to another component, it is to be understood that the component may be directly connected or attached to the other component, but that there may also be other components “interposed” between the respective components which may be indirectly connected or attached where not specifically stated.

When a component or layer is described as “contacting” or “overlapping” another component or layer, the component or layer may directly contact or overlap the other component or layer, but unless there is a specific statement, it should be understood that other components may be interposed between the components that are indirectly contacting or overlapping.

It should be understood that the term “at least one” includes all possible combinations of one or more related components. For example, the meaning of “at least one of the first, second, and third components” includes not only the first, second, or third component, but also any combination of two or more of the first, second, and third components.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

“First direction,” “second direction,” “third direction,” “X-axis direction,” “Y-axis direction,” and “Z-axis direction” should not be interpreted only as geometric relationships that are perpendicular to each other, but may mean a broader directionality within the range that the configuration of the present specification may function.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

The following embodiments may be combined or associated with each other in whole or in part, and various types of interlocking and driving are technically possible. The embodiments may be implemented independently of each other or together in an interrelated relationship.

Hereinafter, preferred embodiments of the present disclosure will be described in detail with reference to the accompanying drawings.

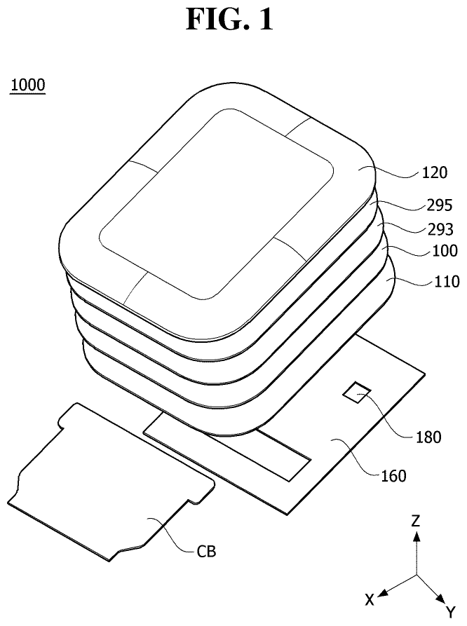

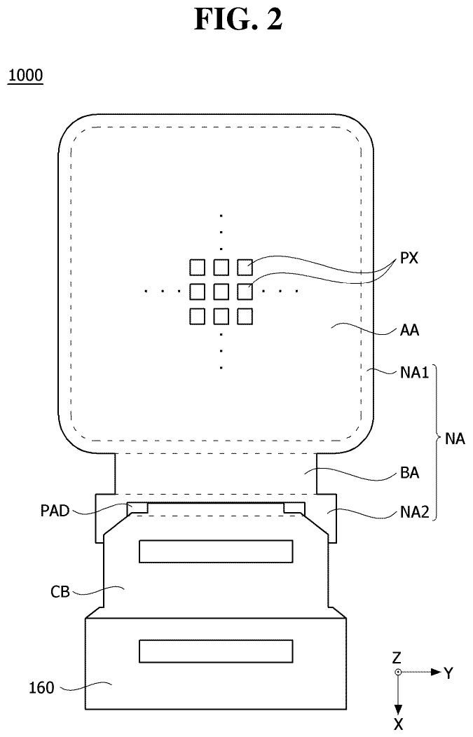

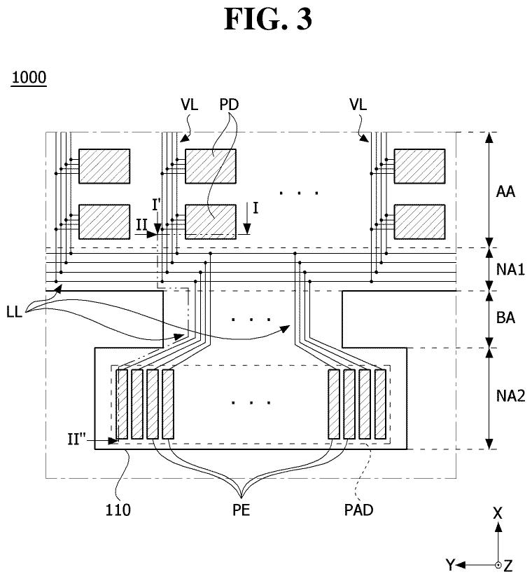

FIG. 1 is an exploded perspective view illustrating a display device according to an embodiment of the present specification. FIG. 2 is a plan view illustrating the display device according to an embodiment of the present specification. FIG. 3 is an enlarged view illustrating the display device according to an embodiment of the present specification.

Referring to FIGS. 1 to 3, the display device 1000 according to an embodiment of the present specification may include the display panel 100, a polarizing layer 293, an adhesive layer 295, a cover 120, a support substrate 110, a flexible circuit board CB, and a printed circuit board 160.

For example, the display device 1000 may include a substrate 110. The substrate 110 may be a component that supports other components of the display device 1000. The substrate 110 may be formed of an insulating material. The substrate 110 may be formed of glass, resin, or the like. Furthermore, the substrate 110 may be formed of a material having flexibility. For example, the substrate 110 may be formed of a plastic material having flexibility, such as polyimide (PI). However, embodiments of the present specification are not limited thereto.

The display panel 100 may implement the display of information, video, and/or images provided to a user. For example, the display panel 100 may include a display area AA and a non-display area NA. For example, the substrate 110 may include the display area AA and the non-display area NA. The display area AA and the non-display area NA are not limited to being described only with respect to the substrate 110 but may be described across the entire display device 1000.

The display area AA may be an area where an image is displayed. The display area AA may include a plurality of pixels PX. Each of the plurality of pixels PX may include a plurality of sub-pixels. A plurality of light emitting elements may be arranged in each of the plurality of sub-pixels. The configuration of the plurality of light emitting elements may vary depending on the type of the display device 1000. For example, in the case where the display device 1000 is an inorganic light emitting display, each of the light emitting elements may be a light-emitting diode (LED), a micro light-emitting diode (micro LED), or a mini light-emitting diode (mini LED); however, embodiments of the present specification are not limited thereto.

The non-display area NA may be an area where no image is displayed. Various wires, circuits, and the like for driving the plurality of pixels PX in the display area AA may be arranged in the non-display area NA. For example, various wires and a driving circuit may be formed in the non-display area NA, and a pad portion PAD, to which an integrated circuit, a printed circuit, and the like are connected, may be located in the non-display area NA; however, embodiments of the present specification are not limited thereto.

For example, the driving circuit may be a data driving circuit and/or a gate driving circuit; however, embodiments of the present specification are not limited thereto. Wires for supply of control signals provided to control the driving circuits may be arranged on the display panel 100. For instance, the control signals may include various timing signals, including a clock signal, an input data enable signal, and synchronization signals; however, embodiments of the present specification are not limited thereto. The control signals may be received through the pad portion PAD. For example, link wires LL for transmitting signals may be arranged in the non-display area NA. For instance, driving components such as the flexible circuit board CB and the printed circuit board 160 may be connected to the pad portion PAD.

According to the present specification, the non-display area NA may include a first non-display area NA1, a bending area BA, and a second non-display area NA2. For example, the first non-display area NA1 may be an area that encloses at least a portion of the display area AA. The bending area BA may be an area extending from at least one of a plurality of sides of the first non-display area NA1 and may be a bendable area. The second non-display area NA2 may be an area extending from the bending area BA. The pad portion PAD may be located in the second non-display area NA2. For example, the bending area BA may be in a bent state, and a remaining area of the substrate 110, other than the bending area BA, may be in a flat state. In this case, as the bending area BA bends, the second non-display area NA2 may be positioned over a rear surface of the display area AA. However, embodiments of the present specification are not limited thereto.

The display area AA of the substrate 110 or the display device 1000 may be formed in various shapes depending on the design of the display device 1000. For example, the display area AA may be formed in a rectangular shape with four rounded corners; however, embodiments of the present specification are not limited thereto. In another example, the display area AA may be formed in a rectangular shape with four right-angled corners or in a circular shape; however, embodiments of the present specification are not limited thereto.

According to the present specification, the width of the second non-display area NA2, in which a plurality of pad electrodes PE are arranged, may be greater than the width of the bending area BA, in which a plurality of link wires LL are arranged. Furthermore, the width of the display area AA, in which a plurality of sub-pixels are arranged, may be greater than the width of the bending area BA, in which the plurality of link wires LL are arranged. Although in the drawings the width of the bending area BA is illustrated as being smaller than that of other areas of the substrate 110, the shape of the substrate 110, including the bending area BA, is merely illustrative, and embodiments of the present specification are not limited thereto.

Referring to FIG. 3, a plurality of pixel driving circuits PD may be arranged in the display area AA. The plurality of pixel driving circuits PD may be circuits configured to drive the light-emitting elements of the plurality of sub-pixels. Each of the plurality of pixel driving circuits PD may include a plurality of transistors including a driving transistor, a storage capacitor, and the like, and may supply control signals, power, and drive current to the light-emitting elements of a plurality of corresponding sub-pixels to control emission operations of the light-emitting elements. For example, each pixel driving circuit PD may include a power wire, and a signal wire provided to control the on/off state of emission and/or the emission time of the light-emitting elements. For instance, the plurality of pixel driving circuits PD may each be a driving driver fabricated on a semiconductor substrate through a metal-oxide-silicon field effect transistor (MOSFET) fabrication process, but embodiments of the present specification are not limited thereto. The driving driver may include a plurality of pixel driving circuits PD and may drive a plurality of sub-pixels.

Referring also to FIG. 1, the flexible circuit board CB and the printed circuit board 160 may be located below the display panel 100. The flexible circuit board CB and the printed circuit board 160 may be located on at least one side edge of the display panel 100, but embodiments of the present specification are not limited thereto. One side of the flexible circuit board CB may be attached to the display panel 100, and another side thereof may be attached to the printed circuit board 160; however, embodiments of the present specification are not limited thereto. The flexible circuit board CB may be a flexible film, but embodiments of the present specification are not limited thereto.

The pad portion PAD including the plurality of pad electrodes PE is located in the second non-display area NA2. A driving component including at least one flexible circuit board (or flexible film) CB and the printed circuit board 160 may be attached or bonded to the pad portion PAD. The plurality of pad electrodes PE of the pad portion PAD may be electrically connected to the at least one flexible circuit board (or flexible film) CB and may transmit various signals (or power) from the printed circuit board 160 and the flexible circuit board (or flexible film) CB to the plurality of pixel driving circuits PD in the display area AA.

The flexible circuit board (or flexible film) CB may be a film in which various components are arranged on a base film having flexibility. For example, a driving integrated circuit (IC), such as a gate driver IC or a data driver IC, may be arranged on the flexible circuit board (or flexible film) CB, but embodiments of the present specification are not limited thereto. The driving IC may be a component that processes data and driving signals for displaying an image. The driving IC may be arranged by a method, such as chip on glass (COG), chip on film (COF), or tape carrier package (TCP), depending on the mounting method; however, embodiments of the present specification are not limited thereto. The flexible circuit board (or flexible film) CB may be attached or bonded onto the plurality of pad electrodes PE through a conductive adhesive layer, but embodiments of the present specification are not limited thereto.

The printed circuit board 160 may be a component that is electrically connected to the at least one flexible circuit board (or flexible film) CB and configured to supply signals to the driving IC. The printed circuit board 160 may be located on one side of the flexible circuit board (or flexible film) CB and may be electrically connected to the flexible circuit board (or flexible film) CB. Various types of components configured to supply different signals to the driving IC may be arranged on the printed circuit board 160. For example, various components, such as a timing controller, a power supply unit, a memory, a processor, or the like may be arranged on the printed circuit board 160. For instance, the printed circuit board 160 may include a power management integrated circuit (PMIC). However, embodiments of the present specification are not limited thereto.

The printed circuit board 160 may include at least one hole 180, but embodiments of the present specification are not limited thereto. An internal component configured to detect ambient light, temperature or the like, which can be provided to a plurality of sensors, may be located in an area corresponding to the at least one hole 180. For example, the internal component may include an ambient light sensor (ALS), a temperature sensor, or the like, but embodiments of the present specification are not limited thereto. For instance, the hole 180 may be a through-hole or the like; however, embodiments of the present specification are not limited thereto.

Referring to FIG. 1, the polarizing layer 293 may be located on the display panel 100. The polarizing layer 293 may prevent or reduce light generated from an external light source from entering the display panel 100 and affecting the light-emitting elements or the like.

The cover 120 may be located on the polarizing layer 293. The cover 120 may be a component provided to protect the display panel 100. The adhesive layer 295 may be located between the polarizing layer 293 and the cover 120. The cover 120 may be attached to the display panel 100 by the adhesive layer 295. The adhesive layer 295 may include an optically clear adhesive (OCA), an optically clear resin (OCR), a pressure sensitive adhesive (PSA), or the like, but embodiments of the present specification are not limited thereto.

The support substrate 110 may be located between the display panel 100 and the printed circuit board 160. The support substrate 110 may reinforce the rigidity of the display panel 100. The support substrate 110 may be a backplate, however, embodiments of the present specification are not limited thereto.

Referring to FIGS. 1 to 3, a plurality of link wires LL may be arranged in the non-display area NA. The plurality of link wires LL may be wires that transmit various signals from the at least one flexible circuit board (or a flexible film) CB and the printed circuit board 160 to the display area AA. The plurality of link wires LL may extend from a plurality of pad electrodes PE in the second non-display area NA2 toward the bending area BA and the first non-display area NA1 and may be electrically connected to a plurality of driving wires VL in the display area AA. The plurality of pixel driving circuits PD may be driven in response to signals received from the at least one flexible circuit board (or flexible film) CB and the printed circuit board 160 through the driving wires VL in the display area AA and the link wires LL in the non-display area NA.

For example, the plurality of driving wires VL, along with a plurality of link wires LL, may be wires provided to transmit signals output from the flexible circuit board (or flexible film) CB and the printed circuit board 160 to the plurality of pixel driving circuits PD. The plurality of driving wires VL may be arranged in the display area AA and may be electrically connected to each of the plurality of pixel driving circuits PD. The plurality of driving wires VL may extend from the display area AA toward the non-display area NA, and may be electrically connected to the plurality of link wires LL. Accordingly, signals output from the flexible circuit board (or flexible film) CB and the printed circuit board 160 may be transmitted to each of the plurality of pixel driving circuits PD through the plurality of link wires LL and the plurality of driving wires VL.

As the bending area BA is bent, portions of the plurality of link wires LL may also be bent. Stress may be concentrated on the bent portions of the link wires LL, which may cause cracks in the link wires LL. Therefore, the plurality of link wires LL may be formed of a conductive material with excellent flexibility to reduce cracks during the bending of the bending area BA. For example, the plurality of link wires LL may be formed of a highly flexible conductive material such as gold (Au), silver (Ag), or aluminum (Al), but embodiments of the present specification are not limited thereto. Furthermore, the plurality of link wires LL may be formed of one of various conductive materials used in the display area AA. For example, the plurality of link wires LL may be formed of molybdenum (Mo), chromium (Cr), titanium (Ti), nickel (Ni), neodymium (Nd), copper (Cu), an alloy of silver (Ag) and magnesium (Mg), or other alloys thereof, but embodiments of the present specification are not limited thereto. The plurality of link wires LL may also be formed in a multilayer structure that includes various conductive materials. For example, a plurality of link wires LL may be formed in a triple-layer structure including titanium (Ti)/aluminum (Al)/titanium (Ti), but embodiments of the present specification are not limited thereto.

The plurality of link wires LL may be configured in various shapes to reduce stress. At least a portion of the plurality of link wires LL that is located in the bending area BA may extend in the same direction as the extension direction of the bending area BA or may extend in a direction different from the extension direction of the bending area BA to reduce stress. For example, in the case where the bending area BA extends in one direction from the first non-display area NA1 toward the second non-display area NA2, at least a portion of the link wires LL that is located in the bending area BA may extend in a direction inclined relative to the one direction. In another example, at least a portion of the plurality of link wires LL may be configured in patterns of various shapes. For instance, at least a portion of the plurality of link wires LL that is located in the bending area BA may have a shape in which a conductive pattern, having at least one of a diamond shape, a rhombus shape, a trapezoidal wave shape, a triangular wave shape, a sawtooth wave shape, a sine wave shape, a circular shape, or an omega (Ω) shape, is repeatedly arranged; however, embodiments of the present specification are not limited thereto. Therefore, to minimize or reduce stress concentrated on the plurality of link wires LL and the resulting cracks, the plurality of link wires LL may have various shapes, including the aforementioned shapes. However, embodiments of the present specification are not limited thereto.

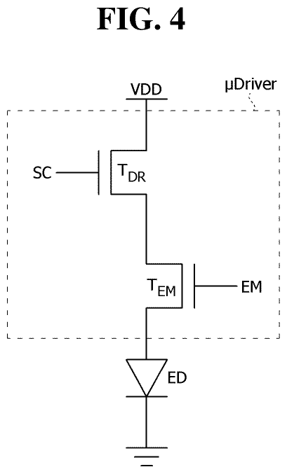

FIG. 4 is a diagram illustrating a circuit structure according to an embodiment of the present specification.

In FIG. 4, an example is illustrated in which a single light-emitting element ED is connected to a micro driver μDriver, but embodiments of the present specification are not limited thereto. For example, eight light-emitting elements ED may be connected to the single micro driver μDriver. In another example, sixteen light-emitting elements ED may be connected to the single micro driver μDriver, or thirty-two or sixty-four light-emitting elements ED may be simultaneously connected to the single micro driver μDriver. The light-emitting element ED may be a micro light-emitting element (μLED).

The single micro driver (μDriver) may include a driving transistor T_{DR} and a light-emitting transistor T_{EM}, but embodiments of the present specification are not limited thereto.

For example, the driving transistor T_{DR} may include a first electrode configured to receive a high-potential power supply voltage VDD, a second electrode connected to a first electrode of the light-emitting transistor T_{EM}, and a gate electrode configured to receive a scan signal SC. The scan signal SC that is applied to the gate electrode of the driving transistor T_{DR} may be a direct current (DC) voltage, and a fixed reference voltage Vref may be applied in each frame; however, embodiments of the present specification are not limited thereto.

The light-emitting transistor T_{EM} may include the first electrode connected to the second electrode of the driving transistor T_{DR}, a second electrode connected to the light-emitting element ED, and a gate electrode configured to receive an emission signal EM. The emission signal EM that is applied to the gate electrode of the light-emitting transistor T_{EM} may be a pulse width modulation (PWM) signal that varies in each frame; however, embodiments of the present specification are not limited thereto.

A first electrode of the light-emitting element ED may be connected to the second electrode of the light-emitting transistor T_{EM}, and a second electrode of the light-emitting element ED may be connected to ground. For example, the first electrode of the light-emitting element ED may be an anode electrode, and the second electrode of the light-emitting element ED may be a cathode electrode; however, embodiments of the present specification are not limited thereto.

The driving transistor T_{DR} and the light-emitting transistor T_{EM} may each be an n-type transistor or a p-type transistor.

In the micro driver μDriver, the driving transistor T_{DR} may be turned on in response to the scan signal SC applied from a timing controller T-CON, and the light-emitting transistor T_{EM} may be turned on in response to the emission signal EM. Accordingly, a drive current may be applied to the light-emitting element ED via the driving transistor T_{DR} and the light-emitting transistor T_{EM} due to the high-potential power supply voltage VDD applied to the first electrode of the driving transistor T_{DR}, thereby allowing the light-emitting element ED to emit light.

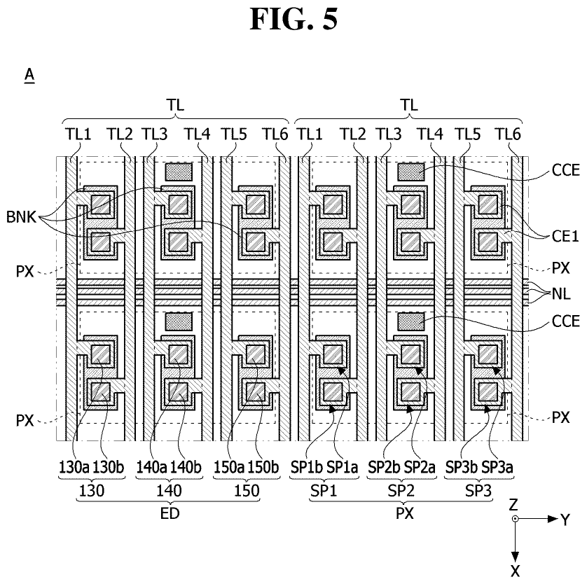

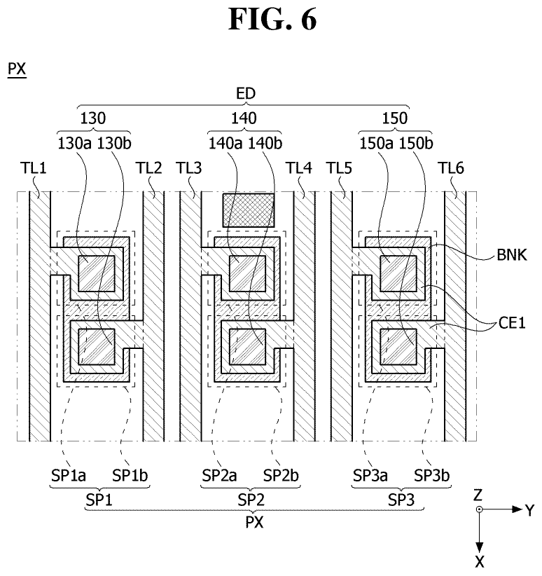

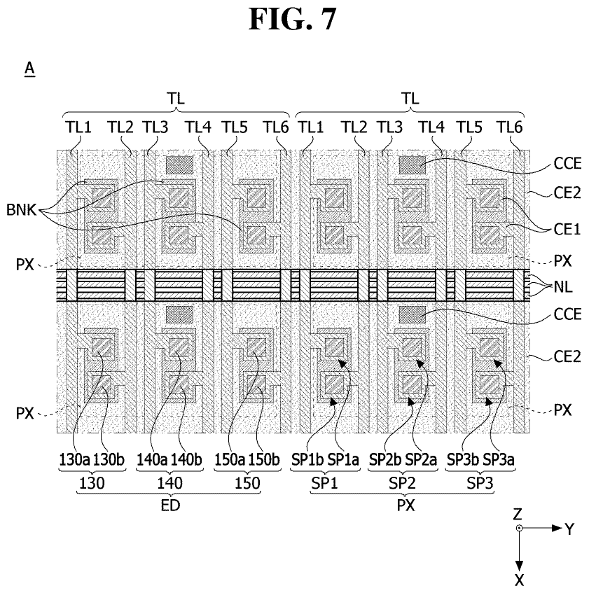

FIGS. 5 to 7 are plan views of the display device according to an embodiment of the present specification. For example, FIG. 5 is an enlarged plan view of a display area in which a plurality of pixels are included. For example, FIG. 6 is an enlarged plan view of a display area in which a single pixel is included. For instance, FIG. 7 is an enlarged plan view of a display area in which a plurality of pixels are included. In FIGS. 5 and 6, only a plurality of signal wires TL, a plurality of communication wires NL, a plurality of first electrodes CE1, a plurality of banks BNK, and a plurality of light-emitting elements ED are illustrated; however, embodiments of the present specification are not limited thereto. FIG. 7 is an enlarged plan view illustrating a plurality of second electrodes CE2 additionally arranged in FIG. 5.

Referring to FIGS. 5 and 6, a plurality of pixels PX, each formed of a plurality of sub-pixels, may be arranged in the display area AA. Each of the plurality of sub-pixels may include a light-emitting element ED and may independently emit light. The plurality of sub-pixels may be arranged in a matrix form including a plurality of rows and a plurality of columns. However, embodiments of the present specification are not limited thereto.

The plurality of sub-pixels may include a first sub-pixel SP1, a second sub-pixel SP2, and a third sub-pixel SP3. For example, any one of the first sub-pixel SP1, the second sub-pixel SP2, or the third sub-pixel SP3 may be a red sub-pixel, another may be a green sub-pixel, and a remaining one may be a blue sub-pixel. The types of the plurality of sub-pixels are illustrative, and embodiments of the present specification are not limited thereto.

Each of the plurality of pixels PX may include at least one first sub-pixel SP1, at least one second sub-pixel SP2, and at least one third sub-pixel SP3. For example, each pixel PX may include a pair of first sub-pixels SP1, a pair of second sub-pixels SP2, and a pair of third sub-pixels SP3. The pair of first sub-pixels SP1 may include a first-first sub-pixel SPla and a first-second sub-pixel SP1b. The pair of second sub-pixels SP2 may include a second-first sub-pixel SP2a and a second-second sub-pixel SP2b. The pair of third sub-pixels SP3 may include a third-first sub-pixel SP3a and a third-second sub-pixel SP3b. For example, each pixel PX may include the first-first sub-pixel SPla and the first-second sub-pixel SP1b, the second-first sub-pixel SP2a and the second-second sub-pixel SP2b, and the third-first sub-pixel SP3a and the third-second sub-pixel SP3b; however, embodiments of the present specification are not limited thereto.

The plurality of sub-pixels that form each pixel PX may be arranged in various ways. For example, in each pixel PX, a pair of first sub-pixels SP1 may be arranged in the same column, a pair of second sub-pixels SP2 may be arranged in the same column, and a pair of third sub-pixels SP3 may be arranged in the same column. The first sub-pixels SP1, the second sub-pixels SP2, and the third sub-pixels SP3 may be arranged in the same row. The number and arrangement of the plurality of sub-pixels that form each pixel PX are illustrative, and embodiments of the present specification are not limited thereto.

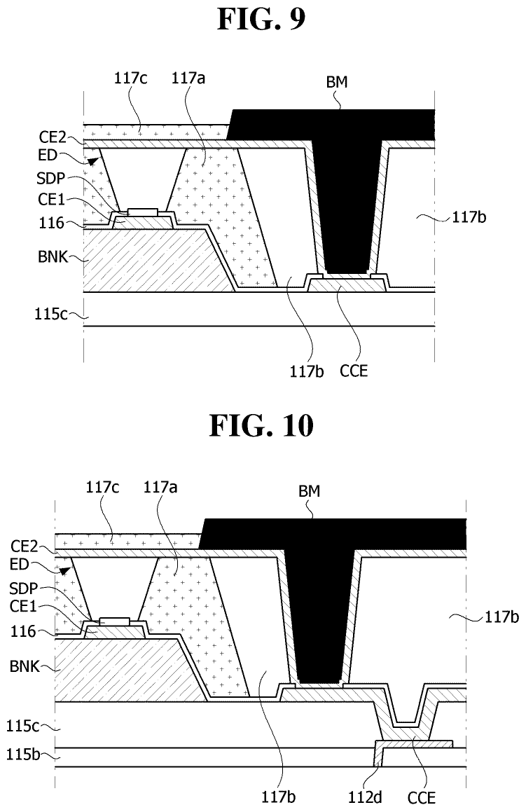

A plurality of signal wires TL may be arranged in an area between the plurality of sub-pixels. The plurality of signal wires TL may extend in a column direction between the plurality of sub-pixels. The plurality of signal wires TL may be wires that transmit an anode voltage from the pixel driving circuit PD to the plurality of sub-pixels. For example, the plurality of signal wires TL may be electrically connected to a plurality of pixel driving circuits PD and the first electrodes CE1 of the plurality of sub-pixels. The anode voltage output from the pixel driving circuit PD may be transmitted to the first electrodes CE1 of the plurality of sub-pixels through the plurality of signal wires TL. For example, the first electrodes CE1 may be electrodes electrically connected to anode electrodes 134 (shown in FIG. 9) of the light-emitting elements ED. Accordingly, the anode voltage from the signal wires TL may be transmitted to the anode electrodes 134 of the light-emitting elements ED through the first electrodes CE1.

Accordingly, the structure of the display device 1000 may be simplified by using the pixel driving circuit PD in which a plurality of pixel circuits are integrated, instead of forming a plurality of transistors and storage capacitors in each of the plurality of sub-pixels. Furthermore, as the circuits respectively arranged in the plurality of sub-pixels are integrated into a single pixel driving circuit PD, high-efficiency and low-power operation may be achieved.

The plurality of signal wires TL may include a first signal wire TL1, a second signal wire TL2, a third signal wire TL3, a fourth signal wire TL4, a fifth signal wire TL5, and a sixth signal wire TL6. The first signal wire TL1 and the second signal wire TL2 may be respectively and electrically connected to the pair of first sub-pixels SP1. The third signal wire TL3 and the fourth signal wire TL4 may be respectively and electrically connected to the pair of second sub-pixels SP2. The fifth signal wire TL5 and the sixth signal wire TL6 may be respectively and electrically connected to the pair of third sub-pixels SP3.

The first signal wire TL1 may be located on one side of the pair of first sub-pixels SP1, and the second signal wire TL2 may be located on another side of the pair of first sub-pixels SP1. The first signal wire TL1 may be electrically connected to the first electrode CE1 of one of the pair of first sub-pixels SP1, for example, the first electrode CE1 of the first-first sub-pixel SPla. The second signal wire TL2 may be electrically connected to the first electrode CE1 of a remaining one of the pair of first sub-pixels SP1, for example, the first electrode CE1 of the first-second sub-pixel SP1b.

The third signal wire TL3 may be located on one side of the pair of second sub-pixels SP2, and the fourth signal wire TL4 may be located on another side of the pair of second sub-pixels SP2. For example, the third signal wire TL3 may be located adjacent to the second signal wire TL2. The third signal wire TL3 may be electrically connected to the first electrode CE1 of one of the pair of second sub-pixels SP2, for example, the first electrode CE1 of the second-first sub-pixel SP2a. The fourth signal wire TL4 may be electrically connected to the first electrode CE1 of a remaining one of the pair of second sub-pixels SP2, for example, the first electrode CE1 of the second-second sub-pixel SP2b.

The fifth signal wire TL5 may be located on one side of the pair of third sub-pixels SP3, and the sixth signal wire TL6 may be located on another side of the pair of third sub-pixels SP3. For example, the fifth signal wire TL5 may be located adjacent to the fourth signal wire TL4. The sixth signal wire TL6 may be located adjacent to the first signal wire TL1 that is connected to an adjacent pixel PX. The fifth signal wire TL5 may be electrically connected to the first electrode CE1 of one of the pair of third sub-pixels SP3, for example, the first electrode CE1 of the third-first sub-pixel SP3a. The sixth signal wire TL6 may be electrically connected to the first electrode CE1 of a remaining one of the pair of third sub-pixels SP3, for example, the first electrode CE1 of the third-second sub-pixel SP3b.

The plurality of signal wires TL may be formed of a conductive material. For example, the plurality of signal wires TL may be formed of a conductive material such as titanium (Ti), aluminum (Al), copper (Cu), molybdenum (Mo), nickel (Ni), chromium (Cr), indium tin oxide (ITO), indium zinc oxide (IZO), or indium gallium zinc oxide (IGZO); however, embodiments of the present specification are not limited thereto. In another example, the plurality of signal wires TL may have a multilayer structure of conductive materials. For example, the plurality of signal wires TL may have a multilayer structure including titanium (Ti)/aluminum (Al)/titanium (Ti)/indium tin oxide (ITO); however, embodiments of the present specification are not limited thereto.

A plurality of communication wires NL may be arranged in an area between the plurality of pixels PX. The plurality of communication wires NL may be arranged to extend in a row direction in the area between the plurality of pixels PX. The plurality of communication wires NL may be arranged in an area between the plurality of second electrodes CE2 and may not overlap the plurality of second electrodes CE2. For example, the plurality of communication wires NL may be wires used for short-range communication such as near field communication (NFC). The plurality of communication wires NL may function as an antenna. For example, the plurality of communication wires NL may be a plurality of connection wires or the like; however, embodiments of the present specification are not limited thereto.

According to the present specification, a bank BNK may be located in each of the plurality of sub-pixels. The plurality of banks BNK may be structures on which the plurality of light-emitting elements ED are seated. The plurality of banks BNK may guide the positions of the plurality of light-emitting elements ED during a transfer process of transferring the plurality of light-emitting elements ED to the display device 1000. During the transfer process of the plurality of light-emitting elements ED, the plurality of light-emitting elements ED may be transferred onto the plurality of banks BNK. The plurality of banks BNK may be a bank pattern, structure, or the like, but embodiments of the present specification are not limited thereto.

The bank BNK of the first sub-pixel SP1, the bank BNK of the second sub-pixel SP2, and the bank BNK of the third sub-pixel SP3 may be spaced apart from each other. The bank BNK of the first sub-pixel SP1, the bank BNK of the second sub-pixel SP2, and the bank BNK of the third sub-pixel SP3 may be configured to be separated. Accordingly, the banks BNK of the first sub-pixel SP1, the second sub-pixel SP2, and the third sub-pixel SP3, onto which different types of light-emitting elements ED are transferred, may be easily identified.

The bank BNK of the first-first sub-pixel SP1a and the bank BNK of the first-second sub-pixel SP1b may be connected to each other or may be formed to be spaced apart or separated. For example, taking into account design factors such as transfer process requirements or the like, the bank BNK of the first-first sub-pixel SP1a and the bank BNK of the first-second sub-pixel SP1b, on which light-emitting elements ED of the same type are arranged, may be connected to each other, or may be spaced apart or separated. The bank BNK of the second-first sub-pixel SP2a and the bank BNK of the second-second sub-pixel SP2b may be connected to each other or may be formed to be spaced apart or separated. The bank BNK of the third-first sub-pixel SP3a and the bank BNK of the third-second sub-pixel SP3b may be connected to each other or may be formed to be spaced apart or separated. Accordingly, the banks BNK of the pair of first sub-pixels SP1, the banks BNK of the pair of second sub-pixels SP2, and the banks BNK of the pair of third sub-pixels SP3 may be formed in various ways, and embodiments of the present specification are not limited thereto.

For instance, the plurality of banks BNK may be formed of an organic insulating material. The plurality of banks BNK may be configured as a single-layer or multilayer structure using an organic insulating material. For example, the plurality of banks BNK may be formed of photoresist, polyimide (PI), an acrylic-based material, or the like, but embodiments of the present specification are not limited thereto.

The first electrode CE1 may be located in each of the plurality of sub-pixels. The first electrode CE1 may be located on the bank BNK. The first electrode CE1 may be electrically connected to one of the plurality of signal wires TL. At least a portion of the first electrode CE1 may extend outward from the bank BNK and may be electrically connected to the signal wire TL that is closest to the first electrode CE1. For example, a portion of the first electrode CE1 of the first-first sub-pixel SP1a may extend to one side area of the first-first sub-pixel SP1a and may be electrically connected to the first signal wire TL1. A portion of the first electrode CE1 of the first-second sub-pixel SP1b may extend to another side area of the first-second sub-pixel SP1b and may be electrically connected to the second signal wire TL2. A portion of the first electrode CE1 of the second-first sub-pixel SP2a may extend to one side area of the second-first sub-pixel SP2a and may be electrically connected to the third signal wire TL3. A portion of the first electrode CE1 of the second-second sub-pixel SP2b may extend to another side area of the second-second sub-pixel SP2b and may be electrically connected to the fourth signal wire TL4. A portion of the first electrode CE1 of the third-first sub-pixel SP3a may extend to one side area of the third-first sub-pixel SP3a and may be electrically connected to the fifth signal wire TL5. A portion of the first electrode CE1 of the third-second sub-pixel SP3b may extend to another side area of the third-second sub-pixel SP3b and may be electrically connected to the sixth signal wire TL6.

The first electrode CE1 may be electrically connected to the anode electrode 134 of the light-emitting element ED and may transmit an anode voltage from the pixel driving circuit PD to the light-emitting element ED through the signal wire TL. Different voltages may be applied to the first electrode CE1 of each of the plurality of sub-pixels depending on an image that is displayed. For example, different voltages may be applied to the respective first electrodes CE1 of the plurality of sub-pixels. Hence, each first electrode CE1 may serve as a pixel electrode; however, embodiments of the present specification are not limited thereto.

The first electrode CE1 may be formed of a conductive material. For example, the first electrode CE1 may be integrally formed with the plurality of signal wires TL. For instance, the first electrode CE1 may be formed of the same conductive material as the plurality of signal wires TL; however, embodiments of the present specification are not limited thereto. For instance, the first electrode CE1 may be formed of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), or the like, but embodiments of the present specification are not limited thereto. In another example, the first electrode CE1 may be formed as a multilayer structure using conductive materials. For instance, the plurality of first electrodes CE1 may be configured as a multilayer structure including titanium (Ti)/aluminum (Al)/titanium (Ti)/indium tin oxide (ITO); however, embodiments of the present specification are not limited thereto.

The light-emitting element ED may be located in each of the plurality of sub-pixels. The plurality of light-emitting elements ED may each be either an LED or a micro LED; however, embodiments of the present specification are not limited thereto. The plurality of light-emitting elements ED may be arranged on the banks BNK and the first electrodes CE1. The plurality of light-emitting elements ED may be arranged on the first electrodes CE1 and may be electrically connected to the first electrodes CE1. Accordingly, each of the light-emitting elements ED may receive an anode voltage from the corresponding pixel driving circuit PD through the corresponding signal wire TL and the associated first electrode CE1, thereby emitting light.

The plurality of light-emitting elements ED may include a first light-emitting element 130, a second light-emitting element 140, and a third light-emitting element 150. The first light-emitting element 130 may be located in the first sub-pixel SP1. The second light-emitting element 140 may be located in the second sub-pixel SP2. The third light-emitting element 150 may be located in the third sub-pixel SP3. For example, any one of the first light-emitting element 130, the second light-emitting element 140, or the third light-emitting element 150 may be a red light-emitting element, another may be a green light-emitting element, and a remaining one may be a blue light-emitting element; however, embodiments of the present specification are not limited thereto. Accordingly, various colors of light, including white, may be implemented by combining the red light, green light, and blue light emitted from the plurality of light-emitting elements ED. The types of the plurality of light-emitting elements ED are illustrative, and embodiments of the present specification are not limited thereto.

The first light-emitting element 130 may include a first-first light-emitting element 130a located in the first-first sub-pixel SP1a, and a first-second light-emitting element 130b located in the first-second sub-pixel SP1b. The second light-emitting element 140 may include a second-first light-emitting element 140a located in the second-first sub-pixel SP2a, and a second-second light-emitting element 140b located in the second-second sub-pixel SP2b. The third light-emitting element 150 may include a third-first light-emitting element 150a located in the third-first sub-pixel SP3a, and a third-second light-emitting element 150b located in the third-second sub-pixel SP3b.

Referring to FIGS. 5, 6, and 7 together, the second electrode CE2 may be located in each of the plurality of sub-pixels. The second electrodes CE2 may be located on the corresponding light-emitting elements ED. The second electrodes CE2 may be electrically connected to the corresponding pixel driving circuits PD through a plurality of contact electrodes CCE.

For example, each second electrode CE2 may be electrically connected to a cathode electrode 135 (shown in FIG. 9) of the corresponding light-emitting element ED, and may transmit a cathode voltage from the pixel driving circuit PD to the light-emitting element ED. The same cathode voltage may be applied to the second electrode CE2 of each of the plurality of sub-pixels. For instance, the same voltage may be applied to the second electrode CE2 of each of the plurality of sub-pixels and the cathode electrode 135 of the light-emitting element ED. Accordingly, the second electrode CE2 may serve as a common electrode; however, embodiments of the present specification are not limited thereto.

At least some of the plurality of sub-pixels may share the second electrode CE2. At least some of the second electrodes CE2 of the plurality of sub-pixels may be electrically connected to each other. As the same voltage is applied to the second electrodes CE2, at least some of the sub-pixels may share the second electrode CE2. For example, the second electrodes CE2 of at least some of the plurality of pixels PX that are arranged in the same row may be connected to each other. For instance, a single second electrode CE2 may be located for a plurality of pixels PX. A single second electrode CE2 may be arranged for every n sub-pixels.

For example, some of the respective second electrodes CE2 of the plurality of sub-pixels may be spaced apart or arranged separately from each other. For instance, the second electrode CE2 connected to the pixels PX that are in an nth row and the second electrode CE2 connected to the pixels PX that are in an (n+1)th row may be spaced apart or arranged separately from each other. For example, the plurality of second electrodes CE2 may be spaced apart from each other with a plurality of communication wires NL interposed therebetween and extending in a row direction. Accordingly, the number of the plurality of sub-pixels may be greater than the number of the plurality of second electrodes CE2. In another example, all of the second electrodes CE2 of the plurality of sub-pixels may be connected to each other such that only one second electrode CE2 is located on the substrate 110, and embodiments of the present specification are not limited thereto.

The plurality of second electrodes CE2 may be formed of a transparent conductive material; however, embodiments of the present specification are not limited thereto. The plurality of second electrodes CE2 may be made of a transparent conductive material, thus allowing light emitted from the light-emitting elements ED to be directed upward above the second electrodes CE2. For example, the second electrodes CE2 may be formed of a transparent conductive material such as indium tin oxide (ITO), indium zinc oxide (IZO), indium gallium zinc oxide (IGZO), or the like; however, embodiments of the present specification are not limited thereto.

The plurality of contact electrodes CCE may be arranged on the substrate 110. For example, the plurality of contact electrodes CCE may be spaced apart from the plurality of banks BNK and the plurality of signal wires TL. Each of the plurality of second electrodes CE2 may overlap at least one contact electrode CCE. For instance, one second electrode CE2 may overlap a plurality of contact electrodes CCE.

For example, the plurality of contact electrodes CCE may be electrically connected to the plurality of second electrodes CE2. The plurality of contact electrodes CCE may be arranged between the substrate 110 and the plurality of second electrodes CE2 and may transmit a cathode voltage from the pixel driving circuits PD to the second electrodes CE2.

For example, in the case where a micro LED (or an inorganic light-emitting element) is used as the light-emitting element ED, the display device 1000 may be fabricated by forming a plurality of micro LEDs on a wafer and transferring the micro LEDs to the substrate 110 of the display device 1000. During the process of transferring the plurality of light-emitting elements ED, each having a micro-size, from the wafer to the substrate 110, various defects may occur. For instance, in some sub-pixels, a non-transfer defect may occur in which the light-emitting element ED is not successfully transferred. In other sub-pixels, a misalignment defect may occur in which the light-emitting element ED is transferred out of an intended position thereof due to alignment errors. Furthermore, even if the transfer process is normally performed, the transferred light-emitting element ED itself may be defective. Accordingly, taking into account defects that may occur during the transfer process of the plurality of light-emitting elements ED, a plurality of light-emitting elements ED of the same type may be transferred to each sub-pixel. A lighting inspection may be performed on the plurality of light-emitting elements ED, and ultimately, only the one light-emitting element ED that is determined to be normal may be used.

For example, both the first-first light-emitting element 130a and the first-second light-emitting element 130b may be transferred together onto a single pixel PX, and presence of defects thereof may be inspected. If both the first-first light-emitting element 130a and the first-second light-emitting element 130b are determined to be normal, the first-first light-emitting element 130a may be used, while the first-second light-emitting element 130b may remain unused. In another example, if the first-second light-emitting element 130b, among the first-first light-emitting element 130a and the first-second light-emitting element 130b, is determined to be normal, the first-first light-emitting element 130a may remain unused, and the first-second light-emitting element 130b may be used. Accordingly, even if a plurality of light-emitting elements ED of the same type are transferred onto each pixel PX, ultimately, only one light-emitting element ED may be used.

Accordingly, any one of the pair of light-emitting elements ED may be a main (or primary) light-emitting element ED, and a remaining light-emitting element ED may be a redundancy light-emitting element ED. The redundancy light-emitting element ED may be an additional light-emitting element ED transferred as a backup in case of failure of the main light-emitting element ED. If the main light-emitting element ED is defective, the redundancy light-emitting element ED may be used as a replacement. Therefore, transferring the main and redundancy light-emitting elements ED together onto a single pixel PX may minimize or reduce the degradation in the display quality due to the defects occurring in the main light-emitting element ED and the redundancy light-emitting element ED.

For example, the first-first light-emitting element 130a, the second-first light-emitting element 140a, and the third-first light-emitting element 150a transferred onto each pixel PX may be used as main light-emitting elements ED. The first-second light-emitting element 130b, the second-second light-emitting element 140b, and the third-second light-emitting element 150b may be used as redundancy light-emitting elements ED.

The display panel 100 according to the present specification includes the first electrode CE1 located below the light-emitting element ED. The light output efficiency may be improved by exposing a portion of a conductive layer with relatively high reflectance among a plurality of conductive layers arranged in the first electrode CE1 through a process such as an etching process. However, during the process of fabricating the display panel 100, the exposed conductive layer of the first electrode CE1 may be exposed to solutions used in various processes, which may cause corrosion or damage to the exposed conductive layer. For example, aluminum included in the first electrode CE1 may be easily corroded when exposed to a solution such as tetramethylammonium hydroxide (TMAH).

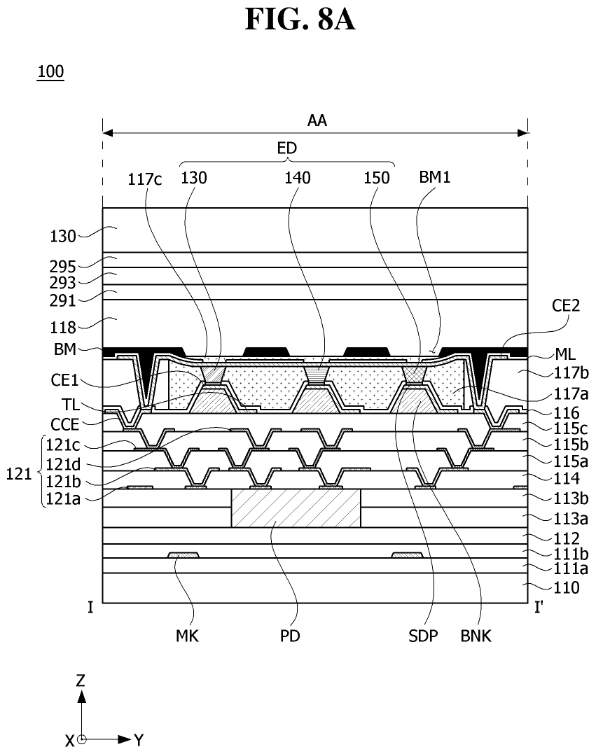

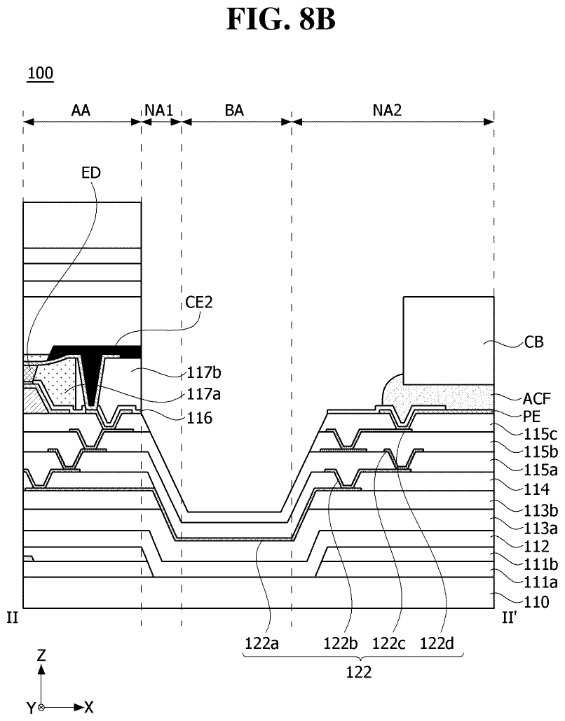

FIGS. 8A and 8B are cross-sectional views of the display device according to an embodiment of the present specification. For example, FIG. 8A is a cross-sectional view of the display area AA taken along line I-I′ of FIG. 3, and FIG. 8B is a cross-sectional view of the first non-display area NA1, the bending area BA, and the second non-display area NA2 taken along line II-II′ of FIG. 3.

FIG. 9 is a cross-sectional view of the display device according to an embodiment of the present specification. FIG. 10 is a cross-sectional view of the display device according to an embodiment of the present specification. As illustrated in FIG. 7, since a plurality of contact electrodes CCE are arranged to overlap with one second electrode CE2 in the Z-axis direction, some of the contact electrodes CCE among the plural contact electrodes CCE may be formed to contact the second electrode CE2, and other contact electrodes CCE may be formed to electrically connect the second electrode CE2 and the first-fourth connection line 121d. For example, FIG. 9 is a cross-sectional view illustrating a contact electrode that only contacts the second electrode, and FIG. 10 is a cross-sectional view illustrating a contact electrode that electrically connects the second electrode and the connection line. Here, among a plurality of contact electrodes CCE, a contact electrode CCE that contacts only the second electrode CE2 may be called a first contact electrode, and a contact electrode CCE that contacts the second electrode CE2 and the first connection line 121 may be called a second contact electrode.

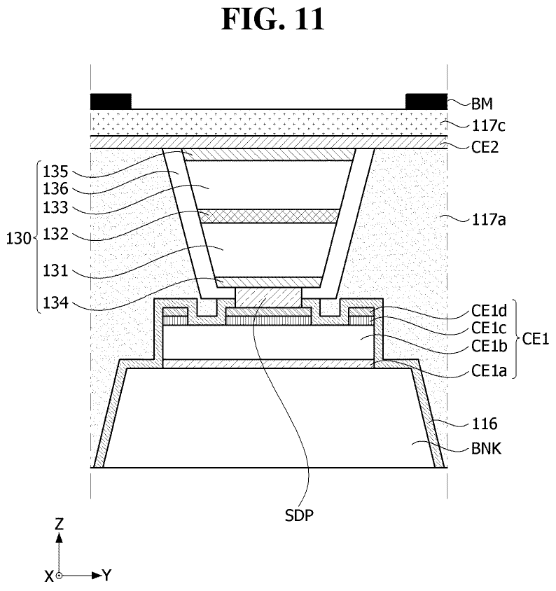

FIG. 11 is a cross-sectional view of the display device according to an embodiment of the present specification. For example, FIG. 11 is a cross-sectional view illustrating a sub-pixel including a light-emitting element arranged in the display area AA.

Referring to FIG. 8A and FIG. 8B, a first buffer layer 111a and a second buffer layer 111b may be arranged in a remaining area of the substrate 110 except for the bending area BA.

The first buffer layer 111a and the second buffer layer 111b may be located in the display area AA, the first non-display area NA1, and the second non-display area NA2. The first buffer layer 111a and the second buffer layer 111b may reduce penetration of moisture or impurities through the substrate 110. The first buffer layer 111a and the second buffer layer 111b may be formed of an inorganic insulating material. For example, the first buffer layer 111a and the second buffer layer 111b may be configured as a single-layer or multilayer structure formed of silicon oxide (SiOx) or silicon nitride (SiNx); however, embodiments of the present specification are not limited thereto.

For example, a portion of the first buffer layer 111a and a portion of the second buffer layer 111b in the bending area BA may be removed. An upper surface of the substrate 110 located in the bending area BA may be exposed from the first buffer layer 111a and the second buffer layer 111b. Cracks that may occur in the first buffer layer 111a and the second buffer layer 111b during bending may be minimized or reduced by removing the first buffer layer 111a and the second buffer layer 111b, which are formed of an inorganic insulating material, from the bending area BA.

A plurality of alignment keys MK may be arranged between the first buffer layer 111a and the second buffer layer 111b. The plurality of alignment keys MK may be configured to identify the position of the pixel driving circuit PD during the process of fabricating the display device 1000. For example, the plurality of alignment keys MK may be configured to align the position of the pixel driving circuit PD, which is transferred onto an adhesive layer 112. In another example, the plurality of alignment keys MK may be omitted.

The adhesive layer 112 may be located on the second buffer layer 111b. The adhesive layer 112 may be located in the display area AA, the first non-display area NA1, the bending area BA, and the second non-display area NA2. In another example, at least a portion of the adhesive layer 112 in the non-display area NA, including the bending area BA, may be removed. For example, the adhesive layer 112 may be formed of any one of an adhesive polymer, epoxy resin, UV-curable resin, a polyimide-based material, an acrylate-based material, a urethane-based material, or polydimethylsiloxane (PDMS); however, embodiments of the present specification are not limited thereto.

In the display area AA, the pixel driving circuit PD may be located on the adhesive layer 112. In the case where the pixel driving circuit PD is implemented as a driving driver, the driving driver may be mounted on the adhesive layer 112 through a transfer process; however, embodiments of the present specification are not limited thereto.

A first protective layer 113a and a second protective layer 113b may be arranged on the adhesive layer 112 and the pixel driving circuit PD. The first protective layer 113a and the second protective layer 113b may be arranged to enclose side surfaces of the pixel driving circuit PD; however, embodiments of the present specification are not limited thereto. For example, the second protective layer 113b may be located to cover at least a portion of an upper surface of the pixel driving circuit PD. For example, at least one of the first protective layer 113a or the second protective layer 113b located in the bending area BA may be omitted. For instance, the first protective layer 113a may be provided throughout the display area AA and the non-display area NA, and the second protective layer 113b may be partially provided in the display area AA, the first non-display area NA1, and the second non-display area NA2. For example, a portion of the second protective layer 113b in the bending area BA may be removed; however, embodiments of the present specification are not limited thereto.

The first protective layer 113a and the second protective layer 113b may be formed of an organic insulating material; however, embodiments of the present specification are not limited thereto. For example, the first protective layer 113a and the second protective layer 113b may be formed of photoresist, polyimide (PI), a photoacrylic-based material, or the like; however, embodiments of the present specification are not limited thereto. For instance, the first protective layer 113a and the second protective layer 113b may each be an overcoating layer or an insulating layer; however, embodiments of the present specification are not limited thereto.

According to the present specification, a plurality of first connection wires 121 may be arranged on the second protective layer 113b in the display area AA. The plurality of first connection wires 121 may be wires for electrically connecting the pixel driving circuit PD to other components. For example, the pixel driving circuit PD may be electrically connected to the plurality of signal wires TL and the plurality of contact electrodes CCE through the plurality of first connection wires 121. For instance, the plurality of first connection wires 121 may include a first-first connection wire 121a, a first-second connection wire 121b, a first-third connection wire 121c, and a first-fourth connection wire 121d; however, embodiments of the present specification are not limited thereto.

For example, the plurality of first-first connection wires 121a may be arranged on the second protective layer 113b. The plurality of first-first connection wires 121a may be electrically connected to the pixel driving circuit PD. The plurality of first-first connection wires 121a may transmit a voltage output from the pixel driving circuit PD to the first electrode CE1 or the second electrode CE2.

For instance, a third protective layer 114 may be located on the second protective layer 113b. The third protective layer 114 may be provided throughout the display area AA and the non-display area NA. In the bending area BA, the third protective layer 114 may cover or enclose a side surface of the second protective layer 113b and an upper surface of the first protective layer 113a. The third protective layer 114 may be formed of an organic insulating material. For example, the third protective layer 114 may be formed of photoresist, polyimide (PI), a photoacrylic-based material, or the like; however, embodiments of the present specification are not limited thereto. For example, the first protective layer 113a, the second protective layer 113b, and the third protective layer 114 may be formed of the same material; however, embodiments of the present specification are not limited thereto.

A plurality of first-second connection wires 121b may be arranged on the third protective layer 114. The plurality of first-second connection wires 121b may be connected to or directly connected to the pixel driving circuit PD. For example, some of the plurality of first-second connection wires 121b may be directly connected to the pixel driving circuit PD through a contact hole of the third protective layer 114. Some others of the first-second connection wires 121b may be electrically connected to the first-first connection wire 121a through a contact hole of the third protective layer 114. However, embodiments of the present specification are not limited thereto. A voltage output from the pixel driving circuit PD may be transmitted to the first electrode CE1 or the second electrode CE2 through the plurality of first-second connection wires 121b and other connection wires.

A first insulating layer 115a may be located on a plurality of first-second connection wires 121b. The first insulating layer 115a may be provided throughout the display area AA and the non-display area NA; however, embodiments of the present specification are not limited thereto. The first insulating layer 115a may be formed of an organic insulating material; however, embodiments of the present specification are not limited thereto. For example, the first insulating layer 115a may be formed of photoresist, polyimide (PI), a photoacrylic-based material, or the like; however, embodiments of the present specification are not limited thereto.

A plurality of first-third connection wires 121c may be arranged on the first insulating layer 115a. The plurality of first-third connection wires 121c may be electrically connected to the plurality of first-second connection wires 121b. For example, the first-third connection wires 121c may be electrically connected to the first-second connection wires 121b through a contact hole of the first insulating layer 115a.

A second insulating layer 115b may be located on the plurality of first-third connection wires 121c. The second insulating layer 115b may be provided in a remaining area except for the bending area BA; however, embodiments of the present specification are not limited thereto. The second insulating layer 115b may be located in the display area AA, the first non-display area NA1, and the second non-display area NA2; however, embodiments of the present specification are not limited thereto. For example, a portion of the second insulating layer 115b that is located in the bending area BA may be removed. The second insulating layer 115b may be formed of an organic insulating material; however, embodiments of the present specification are not limited thereto. For example, the second insulating layer 115b may be formed of photoresist, polyimide (PI), a photoacrylic-based material, or the like; however, embodiments of the present specification are not limited thereto.

A plurality of first-fourth connection wires 121d may be arranged on the second insulating layer 115b. The plurality of first-fourth connection wires 121d may be electrically connected to the plurality of first-third connection wires 121c. For example, the first-fourth connection wires 121d may be electrically connected to the first-third connection wires 121c through a contact hole of the second insulating layer 115b.

According to the present specification, a plurality of second connection wires 122 may be arranged on the second protective layer 113b in the non-display area NA. The plurality of second connection wires 122 may be wires provided to transmit, to the pixel driving circuit PD in the display area AA, signals that are transmitted from the flexible circuit board (or flexible film) CB and the printed circuit board 160 (see FIG. 1) to the pad portion PAD. For example, the plurality of second connection wires 122 may be electrically connected to the plurality of pad electrodes PE and may receive signals from the flexible circuit board (or flexible film) CB and the printed circuit board.

For example, the plurality of second connection wires 122 may extend from the pad portion PAD toward the display area AA and transmit signals to the wires in the display area AA. In this case, the plurality of second connection wires 122 may function as the link wires LL. The plurality of second connection wires 122 may include a second-first connection wire 122a, a second-second connection wire 122b, a second-third connection wire 122c, and a second-fourth connection wire 122d.

A plurality of second-first connection wires 122a may be arranged on the second protective layer 113b. The plurality of second-first connection wires 122a may extend from the second non-display area NA2 to the bending area BA and the first non-display area NA1. The plurality of second-first connection wires 122a may transmit, to the pixel driving circuit PD in the display area AA, signals that are transmitted from the flexible circuit board (or flexible film) CB and the printed circuit board to the pad portion PAD.

A plurality of second-second connection wires 122b may be arranged on the third protective layer 114. The plurality of second-second connection wires 122b may be arranged in the second non-display area NA2. The second-second connection wires 122b may be electrically connected to the second-first connection wires 122a through a contact hole of the third protective layer 114. Accordingly, signals from the flexible circuit board (or flexible film) CB and the printed circuit board may be transmitted to the second-first connection wires 122a through the second-second connection wires 122b.

A plurality of second-third connection wires 122c may be arranged on the first insulating layer 115a. The second-third connection wires 122c may be located in the second non-display area NA2. The second-third connection wires 122c may be electrically connected to the second-second connection wires 122b through a contact hole of the first insulating layer 115a. Accordingly, signals from the flexible circuit board (or flexible film) CB and the printed circuit board may be transmitted to the second-first connection wires 122a through the second-third connection wires 122c and the second-second connection wires 122b.

A plurality of second-fourth connection wires 122d may be arranged on the second insulating layer 115b. The second-fourth connection wires 122d may be located in the second non-display area NA2. The second-fourth connection wires 122d may be electrically connected to the second-third connection wires 122c through a contact hole of the second insulating layer 115b. Accordingly, signals from the flexible film FF and the printed circuit board may be transmitted to the second-first connection wires 122a through the second-fourth connection wires 122d, the second-third connection wires 122c, and the second-second connection wires 122b.

The plurality of first connection wires 121 and the plurality of second connection wires 122 may be formed of either a highly flexible conductive material or any one of various conductive materials applicable to the display area AA. For example, the second connection wires 122, a portion of which is located in the bending area BA, may be formed of a highly flexible conductive material such as gold (Au), silver (Ag), aluminum (Al), or the like; however, embodiments of the present specification are not limited thereto. In another example, the plurality of first connection wires 121 and the plurality of second connection wires 122 may be formed of molybdenum (Mo), chromium (Cr), titanium (Ti), nickel (Ni), neodymium (Nd), copper (Cu), an alloy of silver (Ag) and magnesium (Mg), or other alloys thereof. However, embodiments of the present specification are not limited thereto.

A third insulating layer 115c may be located on the plurality of first connection wires 121 and the plurality of second connection wires 122. The third insulating layer 115c may be located in a remaining area except for the bending area BA; however, embodiments of the present specification are not limited thereto. The third insulating layer 115c may be located in the display area AA, the first non-display area NA1, and the second non-display area NA2. A portion of the third insulating layer 115c in the bending area BA may be removed. The third insulating layer 115c may be formed of an organic insulating material, but embodiments of the present specification are not limited thereto. For example, the third insulating layer 115c may be formed of photoresist, polyimide (PI), a photoacrylic-based material, or the like; however, embodiments of the present specification are not limited thereto.

In the display area AA, the plurality of banks BNK may be arranged on the third insulating layer 115c. The plurality of banks BNK may be arranged to respectively overlap the plurality of sub-pixels. One or more light-emitting elements ED of the same type may be located over each of the plurality of banks BNK.

In the display area AA, the plurality of signal wires TL may be arranged on the third insulating layer 115c. The plurality of signal wires TL may be located in areas between the plurality of banks BNK. For example, the plurality of signal wires TL may be located adjacent to any one of the plurality of banks BNK.

In the display area AA, the plurality of contact electrodes CCE may be arranged on the third insulating layer 115c. The plurality of contact electrodes CCE may each supply a cathode voltage from the pixel driving circuit PD to the corresponding second electrode CE2.

The first electrodes CE1 may each be located on the corresponding bank BNK. For example, the first electrode CE1 may be provided to extend from an adjacent signal wire TL toward an upper portion of the bank BNK. The first electrode CE1 may be formed on both an upper surface and a side surface of the bank BNK. For example, the first electrode CE1 may be provided to extend from the signal wire TL on an upper surface of the third insulating layer 115c to the side surface and the upper surface of the bank BNK.

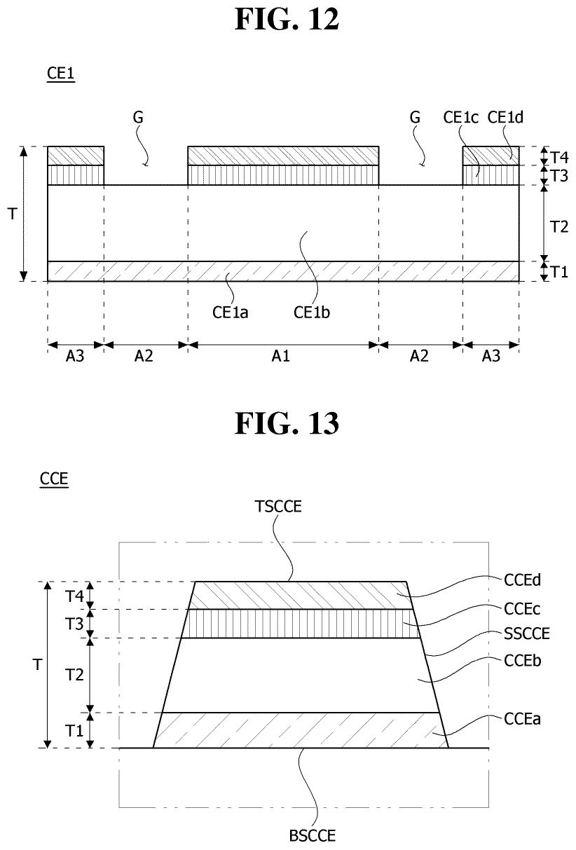

FIG. 12 is a view illustrating a first electrode of the display device according to an embodiment of the present specification. FIG. 13 is a view illustrating a contact electrode of the display device according to an embodiment of the present specification.

Referring to FIG. 9, FIG. 12, and FIG. 13, the first electrode CE1 and the contact electrode CCE may be composed of multiple conductive layers. The first electrode CE1 and the contact electrode CCE may be formed through the same process, and each of the first electrode CE1 and the second electrode CE2 may include the same multiple conductive layers.

Referring to FIGS. 9 and 12, the first electrode CE1 may include a first conductive layer CE1a, a second conductive layer CE1b, a third conductive layer CE1c, and a fourth conductive layer CE1d, but embodiments of the present specification are not limited thereto.

The first conductive layer CE1a may be located on the bank BNK. The second conductive layer CE1b may be located on the first conductive layer CE1a. The third conductive layer CE1c may be located on the second conductive layer CE1b. The fourth conductive layer CE1d may be located on the third conductive layer CE1c. For example, each of the first conductive layer CE1a, the second conductive layer CE1b, the third conductive layer CE1c, and the fourth conductive layer CE1d may be formed of at least one of titanium (Ti), molybdenum (Mo), aluminum (Al), or indium tin oxide (ITO). However, embodiments of the present specification are not limited thereto.

According to the present specification, some conductive layers with high reflection efficiency among the plurality of conductive layers forming the first electrode CE1 may be configured as alignment keys and/or reflectors for aligning the light-emitting element ED. For example, the second conductive layer CE1b among the plurality of conductive layers of the first electrode CE1 may include a reflective material. For instance, the second conductive layer CE1b may include aluminum (Al), but embodiments of the present specification are not limited thereto. Accordingly, the second conductive layer CE1b may be configured as a reflector. Furthermore, the high reflection efficiency of the second conductive layer CE1b may facilitate identification thereof in the manufacturing process. Hence, the position or transfer position of the light-emitting element ED may be aligned based on the second conductive layer CE1b.

For example, to configure the second conductive layer CE1b as a reflector, the third conductive layer CE1c and the fourth conductive layer CE1d that cover the second conductive layer CE1b may be partially removed or etched. For instance, the upper surface of the second conductive layer CE1b may be exposed by removing or etching a portion of the third conductive layer CE1c and a portion of the fourth conductive layer CE1d. For example, except for central portions where a solder pattern SDP is located and perimeter portions (or edge portions) of the third conductive layer CE1c and the fourth conductive layer CE1d, remaining portions may be removed. For instance, the perimeter portion (or edge portion) of each of the third conductive layer CE1c, which is formed of titanium (Ti), and the fourth conductive layer CE1d, which is formed of indium tin oxide (ITO), may remain unetched. Accordingly, in a mask process for forming the first electrode CE1, other conductive layers such as the second conductive layer CE1b of the first electrode CE1 may be protected from corrosion caused by a tetramethylammonium hydroxide (TMAH) solution used in the mask process.

According to the present specification, the first conductive layer CE1a and the third conductive layer CE1c may each include titanium (Ti) or molybdenum (Mo). The second conductive layer CE1b may include aluminum (Al). The fourth conductive layer CE1d may include a transparent conductive oxide layer, such as indium tin oxide (ITO) or indium zinc oxide (IZO), which has excellent adhesion to a solder pattern SDP and exhibits corrosion resistance and acid resistance. However, embodiments of the present specification are not limited thereto.

The first conductive layer CE1a, the second conductive layer CE1b, the third conductive layer CE1c, and the fourth conductive layer CE1d may be sequentially deposited and patterned through a photolithography process and an etching process. However, embodiments of the present specification are not limited thereto.

Referring to FIG. 12, the first electrode CE1 may include the first conductive layer CE1a, the second conductive layer CE1b located on the first conductive layer CE1a, the third conductive layer CE1c located on the second conductive layer CE1b, and the fourth conductive layer CE1d located on the third conductive layer CE1c. The second conductive layer CE1b may be formed of a material having a higher light reflectance than the third conductive layer CE1c and the fourth conductive layer CE1d. For example, the second conductive layer CE1b may include aluminum (Al) or silver (Ag). Accordingly, in the display panel 100 according to the present specification, the second conductive layer CE1b, which has a higher light reflectance than the fourth conductive layer CE1d that is in contact with the solder pattern SDP, may be exposed, thereby improving the light output efficiency of the light-emitting element ED by reflecting light emitted from the light-emitting element ED using the second conductive layer CE1b.

The first electrode CE1 may include the groove G that is formed as a concave shape in the upper surface of the first electrode CE1. The groove G may be formed along the perimeter of the first electrode CE1 and may be arranged to be spaced apart from an edge of the upper surface of the first electrode CE1. The groove G may be formed in the upper surface of the first electrode CE1 through a photolithography process and an etching process; however, embodiments of the present specification are not limited thereto.

A portion of the upper surface of the second conductive layer CE1b may be exposed by the groove G, and the exposed portion of the second conductive layer CE1b may reflect light, which is emitted by the light-emitting element ED and incident on the second conductive layer CE1b through the groove G, thereby improving the light output efficiency of the display device 1000.

As the groove G is formed, the first electrode CE1 may include a first electrode region A1 that the solder pattern SDP contacts, a second electrode region A2 that is arranged on the outside of the first electrode region A1, and a third electrode region A3 that is arranged on the outside of the second electrode region A2, and the second electrode region A2 may be a region where the third conductive layer CE1c and the fourth conductive layer CE1d are not arranged on the second conductive layer CE1b. The second electrode region A2 is a region that reflects light incident on the second conductive layer CE1b through the groove G to thereby improve the light output efficiency and may be called a reflection region.

In FIG. 12, the first electrode CE1 is exemplified as including the first electrode region A1, the second electrode region A2, and the third electrode region A3, but it is not necessarily limited thereto. For example, the third electrode region A3 may be omitted to improve the light output efficiency of the display panel 100. For example, the first electrode CE1 may include only the first electrode region A1 and the second electrode region A2.

The first electrode CE1 may be formed to have a thickness T that is preset by design. In this case, since the first electrode CE1 may be formed by using multiple conductive layers with different resistance values, even if the design specification for the resistance value of the first electrode CE1 is changed, the resistance value of the first electrode CE1 may be obtained by adjusting the thicknesses of the conductive layers. Here, the thickness may refer to the width between one surface and the other surface of a conductive layer arranged in the Z-axis direction.

The first conductive layer CE1a may be formed to have a first thickness T1, where the first thickness T1 may be adjusted. Here, the first conductive layer CE1a may be made of a material having lower light reflectivity but higher resistance compared to the second conductive layer CE1b. For example, the first conductive layer CE1a may include titanium (Ti) or molybdenum (Mo).

The second conductive layer CE1b may be formed to have a second thickness T2 greater than the first thickness T1. Additionally, the second conductive layer CE1b may be made of a material having a higher light reflectivity compared to the third conductive layer CE1c and the fourth conductive layer CE1d. For example, the second conductive layer CE1b may include aluminum (Al) or silver (Ag).

The third conductive layer CE1c may be formed to have a third thickness T3, where the third thickness T3 may be adjusted. The third conductive layer CE1c may be made of a material having lower light reflectivity but higher resistance compared to the second conductive layer CE1b. For example, the third conductive layer CE1c may include titanium (Ti) or molybdenum (Mo).

The fourth conductive layer CE1d may be formed to have a fourth thickness T4, where the fourth thickness T4 may be adjusted. The fourth conductive layer CE1d may be made of a material having a lower light reflectivity compared to the second conductive layer CE1b. For example, the fourth conductive layer CE1d may include a transparent conductive oxide that has good adhesion to the solder pattern SDP and is corrosion-resistant and acid-resistant, such as indium tin oxide (ITO) or indium zinc oxide (IZO).

The thickness of the third conductive layer CE1c and the fourth conductive layer CE1d may be restricted in consideration of the reflection efficiency according to the depth of the groove G; and even if the first electrode CE1 is restricted to have a preset thickness T in the display panel 100 according to the present specification, the resistance value of the first electrode CE1 according to the design specification may be handled by adjusting the thickness of the first conductive layer CE1a and the second conductive layer CE1b.

Referring to FIG. 13, the contact electrode CCE may include a first conductive layer CCEa, a second conductive layer CCEb, a third conductive layer CCEc, and a fourth conductive layer CCEd, but embodiments of the present specification are not limited thereto.

The first conductive layer CCEa may be arranged on the third insulating layer 115c. The second conductive layer CCEb may be arranged on the first conductive layer CCEa. The third conductive layer CCEc may be arranged on the second conductive layer CCEb. The fourth conductive layer CCEd may be arranged on the third conductive layer CCEc. For example, each of the first conductive layer CCEa, the second conductive layer CCEb, the third conductive layer CCEc, and the fourth conductive layer CCEd may be made of at least one of titanium (Ti), molybdenum (Mo), aluminum (Al), and indium tin oxide (ITO), but embodiments of the present specification are not limited thereto.

According to the present specification, the first conductive layer CCEa and the third conductive layer CCEc may include titanium (Ti) or molybdenum (Mo). The second conductive layer CCEb may include aluminum (Al). The fourth conductive layer CCEd may include a transparent conductive oxide layer that has good adhesion to the second electrode CE2 and is corrosion-resistant and acid-resistant, such as indium tin oxide (ITO) or indium zinc oxide (IZO). However, embodiments of the present specification are not limited thereto.

The contact electrode CCE may be formed to have a thickness (T) that is preset by design. In this case, since the contact electrode CCE may be formed by using multiple conductive layers with different resistance values, even if the design specification for the resistance value of the contact electrode CCE is changed, the resistance value of the contact electrode CCE may be obtained by adjusting the thickness of the conductive layers. Here, the contact electrode CCE may include an upper surface TSCCE, a lower surface BSCCE, and a side surface SSCCE connecting the upper surface TSCCE and the lower surface BSCCE. For example, the contact electrode CCE may be formed in a trapezoidal shape including an upper surface TSCCE, a lower surface BSCCE, and a side surface SSCCE, but the shape of the contact electrode CCE is not limited to a trapezoidal shape. For instance, the contact electrode CCE may be formed in a polyhedral shape including an upper surface TSCCE, a lower surface BSCCE, and a side surface SSCCE.

The first conductive layer CCEa may be formed to have a first thickness T1. In addition, the first thickness T1 may be adjusted.

The second conductive layer CCEb may be formed to have a second thickness T2 greater than the first thickness T1.

The third conductive layer CCEc may be formed to have a third thickness T3. In addition, the third thickness T3 may be adjusted.

The fourth conductive layer CCEd may be formed to have a fourth thickness T4. In addition, the fourth thickness T4 may be adjusted.

Even if the contact electrode CCE is restricted to have a preset thickness T in the display panel 100 according to the present specification, considering the process optimization of the contact electrode CCE formed together to have the same layers as the first electrode CE1, only the thickness of the first conductive layer CCEa and the second conductive layer CCEb in the contact electrode CCE may be adjusted like the case of the first electrode CE1. Hence, the resistance value of the contact electrode CCE according to the design specification may be handled by adjusting the thickness of the first conductive layer CCEa and the second conductive layer CCEb.

According to the present specification, the signal wire TL, the contact electrode CCE, and the pad electrode PE that are arranged in the same layer as the first electrode CE1 may be configured as a multilayer structure formed of a conductive material. However, embodiments of the present specification are not limited thereto. For example, the signal wire TL, the contact electrode CCE, and the pad electrode PE may be formed as a multilayer structure including indium tin oxide (ITO)/titanium (Ti)/aluminum (Al)/titanium (Ti). However, embodiments of the present specification are not limited thereto.

According to the present specification, the solder pattern SDP may be located on the first electrode CE1 in each of the plurality of sub-pixels. The solder pattern SDP may bond the light-emitting element ED to the first electrode CE1. The first electrode CE1 and the light-emitting element ED may be electrically connected through eutectic bonding using the solder pattern SDP; however, embodiments of the present specification are not limited thereto. For example, the first electrode CE1 and the anode electrode 134 of the light-emitting element ED may be electrically connected through eutectic bonding using the solder pattern SDP; however, embodiments of the present specification are not limited thereto. For instance, in the case where the solder pattern SDP is formed of indium (In) and the anode electrode 134 of the light-emitting element ED is formed of gold (Au), the solder pattern SDP and the anode electrode 134 may be bonded by applying heat and pressure during the transfer process of the light-emitting element ED. Through eutectic bonding, the light-emitting element ED may be bonded to the solder pattern SDP and the first electrode CE1 without the need for additional adhesive material. For example, the solder pattern SDP may be formed of indium (In), tin (Sn), or an alloy thereof; however, embodiments of the present specification are not limited thereto. For instance, the solder pattern SDP may be a bonding pad, or a junction pad, but embodiments of the present specification are not limited thereto.

According to the present specification, the passivation layer 116 may be arranged on the plural signal lines TL, plural first electrodes CE1, plural contact electrodes CCE, and third insulating layer 115c. For example, the passivation layer 116 may be arranged in the display area AA, first non-display area NA1, and second non-display area NA2. A portion of the passivation layer 116 arranged in the bending area BA may be removed. A portion of the passivation layer 116 covering the plural pad electrodes PE in the second non-display area NA2 may be removed. The passivation layer 116 may be arranged to cover the remaining regions except for the bending area BA, the plural pad electrodes PE, the region where the solder pattern SDP is arranged, and a portion of the contact electrode CCE exposed to be connected to the second electrode CE2, which may reduce the penetration of moisture or impurities into the light-emitting element ED. For example, the passivation layer 116 may be composed of a single layer or multiple layers of silicon oxide (SiOx) or silicon nitride (SiNx), but embodiments of the present specification are not limited thereto. For example, the passivation layer 116 may be a protective layer or an insulating layer, but embodiments of the present specification are not limited thereto. In addition, the passivation layer 116 may be formed to have a thickness of 1000 to 2000 Å being less than the thickness of the second electrode CE2.

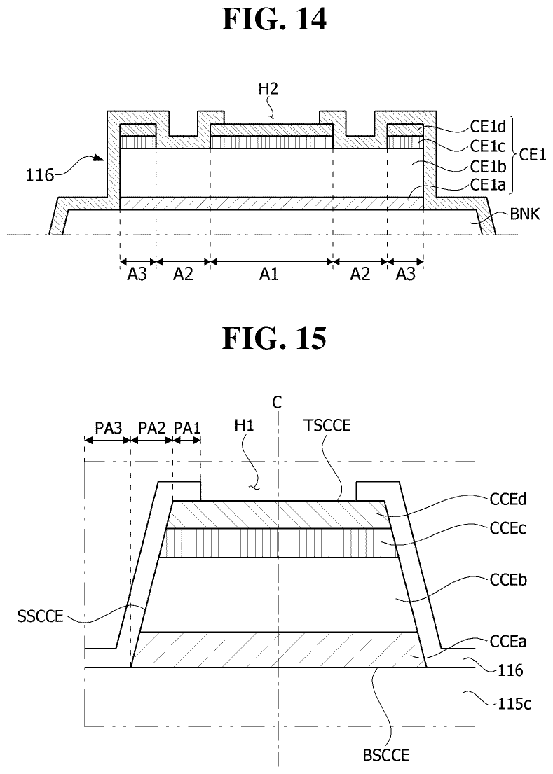

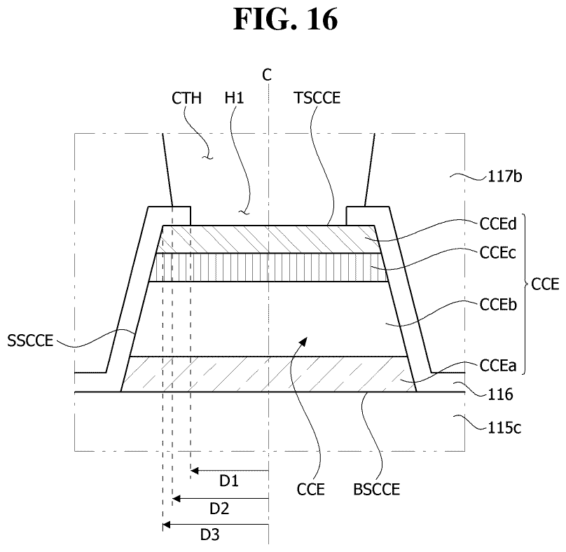

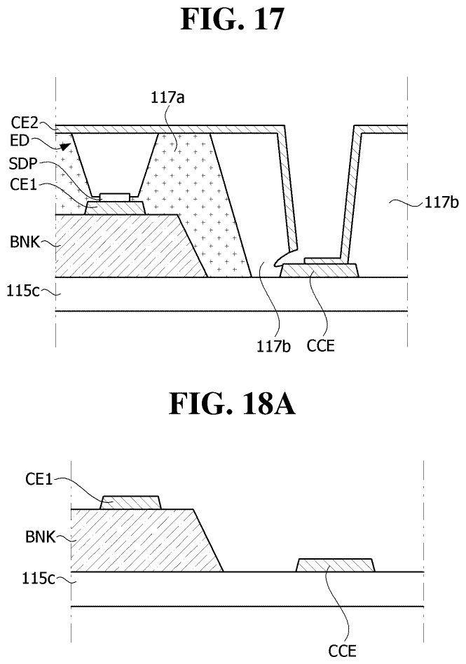

FIG. 14 is a view illustrating the arrangement relationship between the first electrode and the passivation layer in the display device according to an embodiment of the present specification. FIG. 15 is a view illustrating the arrangement relationship between the contact electrode and the passivation layer in the display device according to an embodiment of the present specification. FIG. 16 is a view illustrating the arrangement relationship between the contact electrode, the passivation layer, and the second optical layer in the display device according to an embodiment of the present specification. FIG. 17 is a view illustrating a comparative example. For example, FIG. 17 is a view illustrating a display device in which the passivation layer 116 is removed from the display panel 100 according to an embodiment of the present specification.

Referring to FIGS. 14 and 15, the passivation layer 116 may cover the groove G of the first electrode CE1 to protect the exposed region of the second conductive layer CE1b. In addition, since the adhesion between the contact electrode CC2 and the second optical layer 117b is strengthened by means of the passivation layer 116, when the second electrode CE2 is deposited, the passivation layer 116 may prevent or reduce a disconnection defect in the second electrode CE2 due to a delamination phenomenon. For example, since the adhesion between the contact electrode CC2 and the second optical layer 117b is strengthened by means of the passivation layer 116, the passivation layer 116 may prevent or reduce a delamination phenomenon occurring between the contact electrode CC2 and the second optical layer 117b. Hence, when the second electrode CE2 is deposited, the passivation layer 116 may prevent or reduce a disconnection defect in the second electrode CE2. Here, the passivation layer 116 may include a first hole H1 that exposes the upper surface TSCCE of the contact electrode CCE for connection with the second electrode CE2, and a second hole H2 that exposes the upper surface of the first electrode CE1 for connection with the solder pattern SDP. In this case, the passivation layer 116 may include inner ends forming the first hole H1 and the second hole H2; the inner end of the passivation layer 116 forming the first hole H1 may be called a first inner end, and the inner end of the passivation layer 116 forming the second hole H2 may be called a second inner end.

Referring to FIG. 9 and FIG. 17, the display device according to the comparative example differs from the display device 1000 according to the present specification in that the passivation layer 116 is not present. So, the display device according to the comparative example cannot protect the exposed region of the second conductive layer CE1b arranged on the first electrode CE1. In addition, as shown in FIG. 17, in the case of the display device according to the comparative example, a delamination phenomenon may occur in a region where the inner end of the second optical layer 117b forming the contact hole CHT meets the contact electrode CCE.

Accordingly, the display device 1000 according to the present specification may prevent or reduce a delamination phenomenon that occurs in the display device according to the comparative example while protecting the exposed region of the second conductive layer CE1b by using the passivation layer 116.

Referring to FIG. 12 and FIG. 14, the passivation layer 116 may be arranged to cover the groove G of the first electrode CE1 to thereby protect the exposed second conductive layer CE1b.

For example, to place a solder pattern SDP, an organic insulating material usable as a mask may be deposited on the passivation layer 116, and a portion of the organic material, i.e., a portion of the organic material corresponding to the position where the solder pattern SDP is to be placed, may be exposed by using an exposure process. Next, by using an etching process that removes a portion of the organic insulating material that has reacted to the exposure process through an etching solution, a groove may be formed in the organic insulating material, and then a material forming the solder pattern SDP may be placed inside the groove formed in the organic insulating material, so that the solder pattern SDP may be placed on the first electrode CE1. Then, the organic insulating material used as a mask may be removed through a mask removal process. Here, if the position where the organic insulating material is exposed deviates from the preset position, the exposed upper portion of the second conductive layer CE1b may be exposed to the etching solution used in the etching process, which may damage the second conductive layer CE1b. However, the display panel 100 according to the present specification may prevent or reduce such damage in advance through the passivation layer 116. Accordingly, the display panel 100 according to the present specification may improve the reliability of the manufacturing process through the passivation layer 116.

The passivation layer 116 extended from the upper edge of the first electrode CE1 toward the center of the first electrode CE1 may be arranged to cover the groove G to thereby protect the exposed second conductive layer CE1b. In this case, the end of the passivation layer 116 extended toward the inside of the first electrode CE1 on the first electrode CE1 may overlap with the edge of the first electrode region A1 in the Z-axis direction. Here, the center of the first electrode CE1 may mean the center on the horizontal plane of the first electrode CE1 extended in the X-axis direction and the Y-axis direction. Additionally, the end of the passivation layer 116 extended toward the center of the first electrode CE1 may be the second inner end of the passivation layer 116. Here, since the second inner end of the passivation layer 116 does not extend to the center of the first electrode CE1, the second inner end may form the second hole H2. For example, since the second inner end of the passivation layer 116 is arranged to be spaced apart from the center of the first electrode CE1, the passivation layer 116 may include the second hole H2 in which the solder pattern SDP is placed.

The passivation layer 116 of an inorganic insulating material arranged between the contact electrode CCE and the second optical layer 117b of different materials may prevent or reduce a delamination occurring in a region where the inner end of the second optical layer 117b and the contact electrode CCE meet. Hence, the passivation layer 116 may prevent or reduce a defect in which the second electrode CE2 is disconnected due to delamination during the process of depositing the second electrode CE2.

The passivation layer 116 may be arranged to extend from the third insulating layer 115c to the edge of the upper surface TSCCE of the contact electrode CCE. For example, the first inner end of the passivation layer 116 may be extended toward the center C of the contact electrode CCE, and the first inner end of the passivation layer 116 may be arranged to be spaced apart from the center C of the contact electrode CCE to thereby form the first hole H1. Here, the first inner end of the passivation layer 116 may be placed closer to the center C of the contact electrode CCE than the inner end of the second optical layer 117b. Hence, the contact electrode CCE and the second optical layer 117b may improve adhesion by means of the passivation layer 116 as a medium to thereby preventing or reducing delamination.

The first inner end of the passivation layer 116 extended from the upper edge of the contact electrode CCE to the inside of the contact electrode CCE may overlap with the edge of the contact electrode CCE in the Z-axis direction. Here, the inner side may refer to the direction toward the center C of the contact electrode CCE, and the outer side may refer to the opposite direction of the inner side. In addition, the center C of the contact electrode CCE may mean the center on the horizontal plane of the contact electrode CCE extending in the X-axis direction and the Y-axis direction.

Referring to FIG. 15, the passivation layer 116 may include a first passivation region PA1 in contact with the upper surface TSCCE of the contact electrode CCE, a second passivation region PA2 extended from the first passivation region PA1 to be in contact with the side surface SSCCE of the contact electrode CCE, and a third passivation region PA3 extended from the second passivation region PA2 to be arranged on the third insulating layer 115c.

The first passivation region PA1 may be arranged along the edge of the contact electrode CCE and may extend from the second passivation region PA2 to the inner side. Here, the passivation layer 116 may include the first hole H1 in which the second electrode CE2 is arranged.

The first passivation region PA1 may be arranged between the contact electrode CCE and the inner end of the second optical layer 117b to thereby preventing or reducing delamination that may occur between the contact electrode CCE and the inner end of the second optical layer 117b.

The first passivation region PA1 may include an inner region and an outer region; the second electrode CE2 may be arranged on the inner region of the first passivation region PA1, and the second optical layer 117b may be arranged on the outer region of the first passivation region PA1. Hence, the first passivation region PA1 may come into contact with the second electrode CE2 and the second optical layer 117b, and the second electrode CE2 arranged on the first passivation region PA1 may be extended toward the center C of the contact electrode CCE and be bonded to the contact electrode CCE through the first hole H1, so that the lifting phenomenon of the first inner end of the passivation layer 116 may be prevented or reduced.

The second passivation region PA2 may be a region arranged to cover the side surface SSCCE of the contact electrode CCE, and the second optical layer 117b may be arranged on the second passivation region PA2. Hence, the second passivation region PA2 may block the side surface SSCCE of the contact electrode CCE from being exposed to a chemical solution such as an etching solution.

The third passivation region PA3 may be a region extending from the second passivation region PA2 to the outer side and overlapping with the second optical layer 117b. Here, the third insulating layer 115c may be in contact with the lower portion of the third passivation region PA3.

The passivation layer 116 may further include a fourth passivation region extending from the third passivation region PA3 so as to overlap with the first optical layer 117.

Referring to FIG. 16, with respect to the center C of the contact electrode CCE, the first inner end of the passivation layer 116 may be arranged at a first distance D1, the inner end of the second optical layer 117b forming the contact hole CHT may be arranged at a second distance D2, and the upper surface edge of the second electrode CE2 may be arranged at a third distance D3. Considering the possibility of delamination and manufacturing tolerance, the second distance D2 may be greater than the first distance D1 and less than the third distance D3 so that the second optical layer 117b does not come into contact with the contact electrode CCE, but without being limited thereto. For example, the second distance D2 may be equal to the third distance D3. Hence, the second electrode CE2 may cover the end of the first inner end of the passivation layer 116.

In each of the plurality of sub-pixels, the light-emitting element ED may be located on the solder pattern SDP. A first light-emitting element 130 may be located in a first sub-pixel SP1. A second light-emitting element 140 may be located in a second sub-pixel SP2. A third light-emitting element 150 may be located in a third sub-pixel SP3.

The light-emitting element ED may be formed on a silicon wafer by a method such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), sputtering, or the like. However, embodiments of the present specification are not limited thereto.

Referring to FIG. 11, the first light-emitting element 130 may include an anode electrode 134, a first semiconductor layer 131, an active layer 132, a second semiconductor layer 133, a cathode electrode 135, and an encapsulation film 136. However, embodiments of the present specification are not limited thereto. For example, the first light-emitting element 130 may not include the encapsulation film 136.

The first semiconductor layer 131 may be located on the solder pattern SDP. The second semiconductor layer 133 may be located on the first semiconductor layer 131.

For example, either the first semiconductor layer 131 or the second semiconductor layer 133 may be implemented with a compound semiconductor such as a III-V group or II-VI group semiconductor, or the like, and may be doped with an impurity (or dopant). For instance, either the first semiconductor layer 131 or the second semiconductor layer 133 may be an n-type doped semiconductor layer, and the other may be a p-type doped semiconductor layer. However, embodiments of the present specification are not limited thereto. For example, at least one of the first semiconductor layer 131 or the second semiconductor layer 133 may be a layer formed by doping a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs), with an n-type or p-type impurity. However, embodiments of the present specification are not limited thereto. For example, the n-type impurity may include silicon (Si), germanium (Ge), selenium (Se), carbon (C), tellurium (Te), or tin (Sn); however, embodiments of the present specification are not limited thereto. For example, the p-type impurity may include magnesium (Mg), zinc (Zn), calcium (Ca), strontium (Sr), barium (Ba), beryllium (Be), or the like, but embodiments of the present specification are not limited thereto.

For example, the first semiconductor layer 131 and the second semiconductor layer 133 may be respectively formed of a nitride semiconductor including an n-type impurity and a nitride semiconductor including a p-type impurity. However, embodiments of the present specification are not limited thereto. For instance, the first semiconductor layer 131 may be a nitride semiconductor including a p-type impurity, and the second semiconductor layer 133 may be a nitride semiconductor including an n-type impurity; however, embodiments of the present specification are not limited thereto.

The active layer 132 may be located between the first semiconductor layer 131 and the second semiconductor layer 133. The active layer 132 may receive holes and electrons from the first semiconductor layer 131 and the second semiconductor layer 133 and emit light. For example, the active layer 132 may be formed in one of a single well structure, a multiple well structure, a single quantum well structure, a multi-quantum well (MQW) structure, a quantum dot structure, or a quantum wire structure. However, embodiments of the present specification are not limited thereto. For instance, the active layer 132 may be formed of indium gallium nitride (InGaN), gallium nitride (GaN), or the like; however, embodiments of the present specification are not limited thereto.

In another example, the active layer 132 may include a multi-quantum well (MQW) structure having a well layer and a barrier layer with a higher band gap than the well layer. For instance, the active layer 132 may be configured with a well layer formed of InGaN and a barrier layer formed of AlGaN. However, embodiments of the present specification are not limited thereto.

The anode electrode 134 may be located between the first semiconductor layer 131 and the solder pattern SDP. For example, the anode electrode 134 may electrically connect the first semiconductor layer 131 and the first electrode CE1. An anode voltage output from the pixel driving circuit PD may be applied to the first semiconductor layer 131 through the signal wire TL, the first electrode CE1, and the anode electrode 134. For instance, the anode electrode 134 may be formed of a conductive material capable of eutectic bonding with the solder pattern SDP; however, embodiments of the present specification are not limited thereto. For example, the anode electrode 134 may be formed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), copper (Cu), or an alloy thereof. However, embodiments of the present specification are not limited thereto.

The cathode electrode 135 may be located on the second semiconductor layer 133. For example, the cathode electrode 135 may electrically connect the second semiconductor layer 133 and the second electrode CE2. A cathode voltage output from the pixel driving circuit PD may be applied to the second semiconductor layer 133 through the contact electrode CCE, the second electrode CE2, and the cathode electrode 135. The cathode electrode 135 may be formed of a transparent conductive material to allow light emitted from the light-emitting element ED to pass upward above the light-emitting element ED. However, embodiments of the present specification are not limited thereto. For instance, the cathode electrode 135 may be formed of a material such as indium tin oxide (ITO), indium zinc oxide (IZO), indium gallium zinc oxide (IGZO), or the like; however, embodiments of the present specification are not limited thereto.

The encapsulation film 136 may be located on at least a portion of the first semiconductor layer 131, the active layer 132, the second semiconductor layer 133, the anode electrode 134, and the cathode electrode 135. For example, the encapsulation film 136 may enclose at least a portion of the first semiconductor layer 131, the active layer 132, the second semiconductor layer 133, the anode electrode 134, and the cathode electrode 135.

For example, the encapsulation film 136 may protect the first semiconductor layer 131, the active layer 132, and the second semiconductor layer 133. For instance, the encapsulation film 136 may be located on a side surface of the first semiconductor layer 131, a side surface of the active layer 132, and a side surface of the second semiconductor layer 133.

For example, the encapsulation film 136 may be located on at least a portion of the anode electrode 134 and the cathode electrode 135, e.g., an edge portion (or peripheral portion or one side) of the anode electrode 134 and an edge portion (or peripheral portion or one side) of the cathode electrode 135. At least a portion of the anode electrode 134 may be exposed from the encapsulation film 136, allowing the anode electrode 134 to be connected to the solder pattern SDP. For instance, at least a portion of the cathode electrode 135 may be exposed from the encapsulation film 136, allowing the cathode electrode 135 to be connected to the second electrode CE2. For example, the encapsulation film 136 may be formed of an insulating material such as silicon nitride (SiNx) or silicon oxide (SiOx); however, embodiments of the present specification are not limited thereto.

In another example, the encapsulation film 136 may have a structure in which a reflective material is dispersed in a resin layer. However, embodiments of the present specification are not limited thereto. For example, the encapsulation film 136 may be formed as a reflector with various structures; however, embodiments of the present specification are not limited thereto. The encapsulation film 136 may reflect light, which is emitted from the active layer 132, upward, thereby improving light extraction efficiency. For instance, the encapsulation film 136 may be a reflective layer; however, embodiments of the present specification are not limited thereto.

According to the present specification, although the light-emitting element ED has been described with a vertical structure, embodiments of the present specification are not limited thereto. For example, the light-emitting element ED may have a lateral structure or a flip-chip structure.

Although the first light-emitting element 130 has been described with reference to FIG. 11, the second light-emitting element 140 and the third light-emitting element 150 may have substantially the same structure as the first light-emitting element 130. For example, the second light-emitting element 140 and the third light-emitting element 150 may have substantially the same components as the first light-emitting element 130, including the first semiconductor layer 131, the active layer 132, the second semiconductor layer 133, the anode electrode 134, the cathode electrode 135, and the encapsulation film 136.

According to the present specification, a first optical layer 117a may enclose the plurality of light-emitting elements ED in the display area AA. For example, the first optical layer 117a may be formed to cover the plurality of light-emitting elements ED and the banks BNK in the respective areas of the plurality of sub-pixels. For instance, the first optical layer 117a may cover the banks BNK, a portion of the passivation layer 116, and spaces between the plurality of light-emitting elements ED. The first optical layer 117a may be located between or cover the spaces between the plurality of light-emitting elements ED included in each pixel PX and the spaces between the plurality of banks BNK. For instance, the first optical layer 117a may extend in a first direction (X-axis direction) and have spacing in a second direction (Y-axis direction). For example, the first optical layer 117a may be formed to enclose the side surfaces of the light-emitting elements ED and the banks BNK between the passivation layer 116 and the second electrode CE2; however, embodiments of the present specification are not limited thereto. For instance, the first optical layer 117a may be a diffusion layer or a sidewall diffusion layer, but embodiments of the present specification are not limited thereto.

The first optical layer 117a may include an organic insulating material in which fine particles are dispersed. However, embodiments of the present specification are not limited thereto. For example, the first optical layer 117a may be formed of siloxane in which fine metal particles, such as titanium dioxide (TiO₂) particles, are dispersed, but embodiments of the present specification are not limited thereto. Light emitted from the plurality of light-emitting elements ED may be scattered by the fine particles dispersed in the first optical layer 117a and then emitted to the outside of the display device 1000. Accordingly, the first optical layer 117a may enhance the extraction efficiency of the light emitted from the plurality of light-emitting elements ED.

For example, the first optical layer 117a may be located in each of the plurality of pixels PX or may be located in some pixels PX that are arranged in the same row. However, embodiments of the present specification are not limited thereto. For example, the first optical layer 117a may be provided in each of the plurality of pixels PX, or the plurality of pixels PX may share a single first optical layer 117a. In another example, each of the plurality of sub-pixels may separately include the first optical layer 117a, but embodiments of the present specification are not limited thereto.

According to the present specification, a second optical layer 117b may be located on the passivation layer 116 in the display area AA. For example, the second optical layer 117b may be formed to enclose the first optical layer 117a. For instance, the second optical layer 117b may be in contact with a side surface of the first optical layer 117a. For example, the second optical layer 117b may be located in an area between the plurality of pixels PX. However, embodiments of the present specification are not limited thereto. For example, the second optical layer 117b may be a diffusion layer, a diffusion layer window, a window diffusion layer, or the like, but embodiments of the present specification are not limited thereto.

The second optical layer 117b may be formed of an organic insulating material; however, embodiments of the present specification are not limited thereto. The second optical layer 117b may be formed of the same material as the first optical layer 117a; however, embodiments of the present specification are not limited thereto. For example, the first optical layer 117a may include fine particles, and the second optical layer 117b may not include fine particles. For example, the second optical layer 117b may be formed of siloxane; however, embodiments of the present specification are not limited thereto.

For example, the thickness of the first optical layer 117a may be smaller than that of the second optical layer 117b, but embodiments of the present specification are not limited thereto. Accordingly, in a plan view, the area where the first optical layer 117a is located may include a concave portion that is recessed inward relative to an upper surface of the second optical layer 117b.

According to the present specification, the second electrode CE2 may be located on the first optical layer 117a and the second optical layer 117b. For example, the second electrode CE2 may be electrically connected to the plurality of contact electrodes CCE through a contact hole of the second optical layer 117b. For example, the second electrode CE2 may be located on the plurality of light-emitting elements ED. For instance, the second electrode CE2 may include a transparent conductive oxide such as indium tin oxide (ITO) or indium zinc oxide (IZO); however, embodiments of the present specification are not limited thereto. For example, the second electrode CE2 may be located in contact with the cathode electrode 135. For instance, the second electrode CE2 may overlap the first optical layer 117a. For example, the second electrode CE2 may cover an outer planar surface of the first optical layer 117a.

The second electrode CE2 may extend continuously in the first direction (X-axis direction) of the substrate 110. Accordingly, the second electrode CE2 may be connected in common to the plurality of pixels PX that are arranged in the first direction (X-axis direction) of the substrate 110. For example, the second electrode CE2 may be connected in common to the plurality of pixels PX.

According to the present specification, the second electrode CE2 may extend continuously on the first optical layer 117a, the second optical layer 117b, and the light-emitting element ED. The area where the first optical layer 117a is located may include a concave portion that is recessed inward relative to the upper surface of the second optical layer 117b. Accordingly, a first portion of the second electrode CE2 located on the first optical layer 117a may be provided along the concave portion and, therefore, may be positioned lower than a second portion of the second electrode CE2 located on the second optical layer 117b.

A third optical layer 117c may be located on the second electrode CE2. The third optical layer 117c may be located to overlap the plurality of light-emitting elements ED and the first optical layer 117a. Since the third optical layer 117c is located on the second electrode CE2 and the plurality of light-emitting elements ED, mura may be prevented or reduced from occurring in some of the plurality of light-emitting elements ED. For example, when the plurality of light-emitting elements ED are transferred onto the substrate 110 of the display device 1000, process deviations or other factors may result in non-uniform spacing between the plurality of light-emitting elements ED. If the spacing between the plurality of light-emitting elements ED is non-uniform, respective light output areas of the plurality of light-emitting elements ED may be arranged non-uniformly, making mura visible to a user. Taking into account the aforementioned issue, the third optical layer 117c may be configured to uniformly diffuse light over the plurality of light-emitting elements ED, thereby reducing the perception of mura caused by light emission from some light-emitting elements ED. Therefore, the third optical layer 117c enables light emitted from the plurality of light-emitting elements ED to be evenly diffused and extracted to the outside of the display device 1000, thereby improving the luminance uniformity of the display device 1000.

The third optical layer 117c may be formed of an organic insulating material in which fine particles are dispersed. However, embodiments of the present specification are not limited thereto. For example, the third optical layer 117c may be formed of siloxane in which fine metal particles, such as titanium dioxide (TiO₂) particles, are dispersed; however, embodiments of the present specification are not limited thereto. For example, the third optical layer 117c may be formed of the same material as the first optical layer 117a, but embodiments of the present specification are not limited thereto. For example, the third optical layer 117c may be a diffusion layer or an upper surface diffusion layer. However, embodiments of the present specification are not limited thereto.

According to the present specification, light emitted from the plurality of light-emitting elements ED may be scattered by the fine particles dispersed in the third optical layer 117c and emitted to the outside of the display device 1000. The third optical layer 117c may evenly mix the light emitted from the plurality of light-emitting elements ED, thereby further improving the luminance uniformity of the display device 1000. In addition, scattering the light using the plurality of fine particles may enhance the light extraction efficiency of the display device 1000, thereby enabling the display device 1000 to operate with lower power consumption.

In the display area AA, a black matrix BM may be located on the second electrode CE2, the first optical layer 117a, the second optical layer 117b, and the third optical layer 117c. For example, the black matrix BM may fill the contact hole of the second optical layer 117b. Because the black matrix BM is configured to cover the display area AA, the black matrix BM may reduce color mixing of light from the plurality of sub-pixels and reflection of external light. For example, the black matrix BM may also be located in the contact hole through which the second electrode CE2 and the contact electrode CCE are connected, thereby preventing or reducing light leakage between adjacent sub-pixels.

For example, the black matrix BM may be formed of an opaque material. However, embodiments of the present specification are not limited thereto. For instance, the black matrix BM may be an organic insulating material containing a black pigment or a black dye, but embodiments of the present specification are not limited thereto.

In the display area AA, a cover layer 118 may be located on the black matrix BM. The cover layer 118 may protect components provided under the cover layer 118. For example, the cover layer 118 may be formed of an organic insulating material; however, embodiments of the present specification are not limited thereto. For example, the cover layer 118 may be formed of photoresist, polyimide (PI), a photoacryl-based material, or the like, but embodiments of the present specification are not limited thereto. For instance, the cover layer 118 may be an overcoating layer, an insulating layer, or the like. However, embodiments of the present specification are not limited thereto.

The polarizing layer 293 may be located on the cover layer 118 via a first adhesive layer 291. The cover 120 may be located on the polarizing layer 293 via a second adhesive layer 295. For example, the first adhesive layer 291 and the second adhesive layer 295 may each include an optically clear adhesive (OCA), an optically clear resin (OCR), a pressure-sensitive adhesive (PSA), or the like. However, embodiments of the present specification are not limited thereto.

According to the present specification, in the second non-display area NA2, the plurality of pad electrodes PE may be arranged on the third insulating layer 115c. For example, at least a portion of each of the plurality of pad electrodes PE may be exposed from the passivation layer 116. For example, the plurality of pad electrodes PE may be electrically connected to the second-fourth connection wires 122d through contact holes of the third insulating layer 115c.

An adhesive layer ACF may be located on the plurality of pad electrodes PE. The adhesive layer ACF may be an adhesive layer in which conductive balls are dispersed in an insulating material, but embodiments of the present specification are not limited thereto. In the case where heat or pressure is applied to the adhesive layer ACF, the conductive balls in the area where heat or pressure is applied may be electrically connected, thereby exhibiting conductive properties. The flexible circuit board (or the flexible film) CB may be attached or bonded to the plurality of pad electrodes PE by locating the adhesive layer ACF between the plurality of pad electrodes PE and the flexible circuit board (or flexible film) CB. For example, the adhesive layer ACF may be an anisotropic conductive film (ACF), but embodiments of the present specification are not limited thereto.

The flexible circuit board (or a flexible film) CB may be located on the adhesive layer ACF. The flexible circuit board (or the flexible film) CB may be electrically connected to the plurality of pad electrodes PE through the adhesive layer ACF. Accordingly, signals output from the flexible circuit board (or the flexible film) CB and the printed circuit board may be transmitted to the pixel driving circuit PD in the display area AA through the plurality of pad electrodes PE, the second-fourth connection wire 122d, the second-third connection wire 122c, the second-second connection wire 122b, and the second-first connection wires 122a.

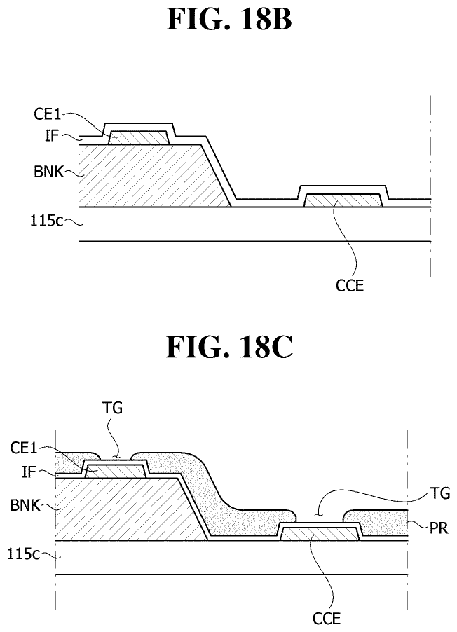

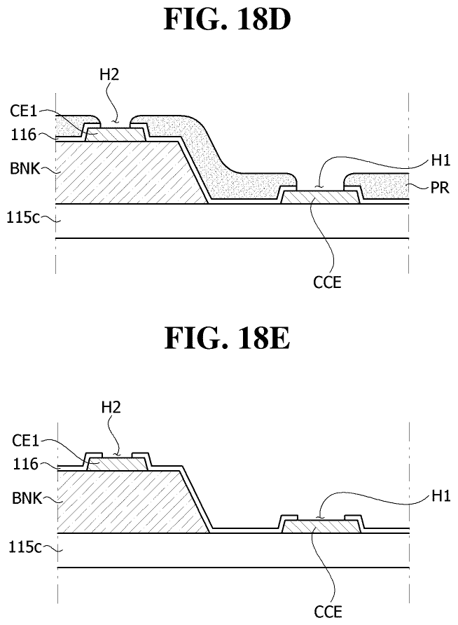

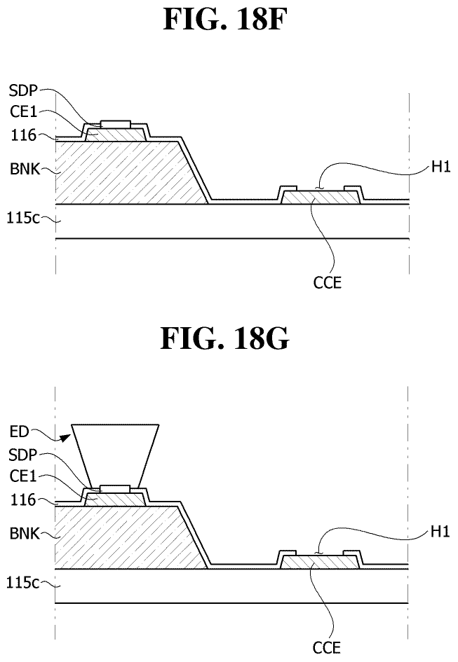

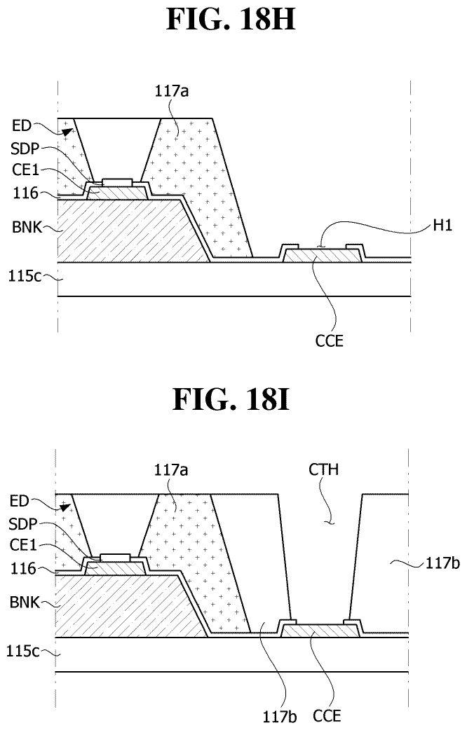

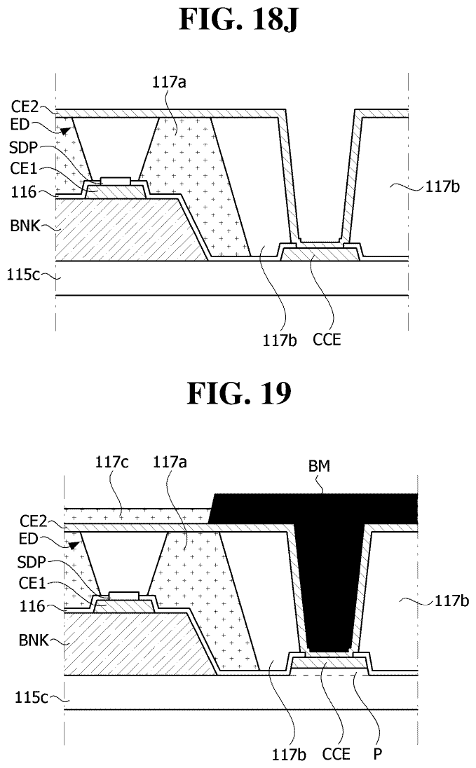

FIGS. 18A to 18J are views illustrating a process of forming first electrode, contact electrode, passivation layer, solder pattern, light-emitting element, first optical layer, second optical layer, and second electrode of a display device according to an embodiment of the present specification. For example, FIG. 18A is a view showing a first electrode CE1 arranged on the bank BNK and a contact electrode CCE arranged on the third insulating layer 115c. FIG. 18B is a view showing an inorganic insulating film arranged to form a passivation layer 116 that covers the bank BNK, first electrode CE1, third insulating layer 115c, and contact electrode CCE. FIG. 18C is a view showing a mask member arranged on the inorganic insulating film. FIG. 18D is a view showing the passivation layer 116 in which a first hole H1 and a second hole H2 are formed. FIG. 18E is a view showing the state where the mask member is removed from the passivation layer 116 in which the first hole H1 and the second hole H2 are formed. FIG. 18F is a view showing a solder pattern SDP arranged in the second hole H2 of the passivation layer 116. FIG. 18G is a view showing a light-emitting element ED arranged on the solder pattern SDP. FIG. 18H is a view showing a first optical layer 117a arranged around the light-emitting element ED. FIG. 18I is a view showing a second optical layer 117b arranged around the light-emitting element ED. FIG. 18J is a view showing a second electrode CE2 arranged in contact with the light-emitting element ED and the contact electrode CCE.

Referring to FIG. 18A, the first electrode CE1 may be arranged on the bank BNK, and the contact electrode CCE may be arranged on the third insulating layer 115c. The first electrode CE1 and the contact electrode CCE may be formed to have the same materials by using the same process. For example, the first electrode CE1 may include a first conductive layer CE1a, a second conductive layer CE1b, a third conductive layer CE1c, and a fourth conductive layer CE1d, which are stacked in sequence, and the contact electrode CCE may include a first conductive layer CCEa, a second conductive layer CCEb, a third conductive layer CCEc, and a fourth conductive layer CCEd, which are stacked in sequence. The materials of the first conductive layer CE1a of the first electrode CE1 and the first conductive layer CCEa of the contact electrode CCE may be the same, the materials of the second conductive layer CE1b of the first electrode CE1 and the second conductive layer CCEb of the contact electrode CCE may be the same, the materials of the third conductive layer CE1c of the first electrode CE1 and the third conductive layer CCEc of the contact electrode CCE may be the same, and the materials of the fourth conductive layer CE1d of the first electrode CE1 and the fourth conductive layer CCEd of the contact electrode CCE may be the same. Hence, it is possible to improve the productivity of the display panel 100 by optimizing the manufacturing process of the first electrode CE1 and the contact electrode CCE.

Referring to FIG. 18B, an inorganic insulating film IF to form the passivation layer 116 may be deposited on the bank BNK, first electrode CE1, third insulating layer 115c, and contact electrode CCE. Hence, the inorganic insulating film IF may cover the bank BNK, the first electrode CE1, the third insulating layer 115c, and the contact electrode CCE.

Referring to FIG. 18C, a mask member PR may be arranged on the inorganic insulating film IF. In this case, through grooves TG may be formed in the mask member PR in correspondence to the first hole H1 and the second hole H2 of the passivation layer 116. The through groove TG may be formed through an exposure process and an etching process in which an etching solution is sprayed onto a region of the mask member PR that has reacted to the exposure process to remove it. The mask member PR may include an organic insulating material. For example, the mask member PR may be, but not limited to, a photoresist.

Referring to FIG. 18D, the first hole H1 and the second hole H2 of the passivation layer 116 may be formed by using an etching solution or the like supplied through the through groove TG. As a result, a portion of the upper surface of the first electrode CE1 and a portion of the upper surface of the contact electrode CCE may be exposed.

Referring to FIG. 18E, the mask member PR may be removed through a process of removing the mask member PR. For example, the mask member (PR), which is an organic insulating material used as a mask, may be removed through a mask removal process using an etching solution. Here, the etching solution used in the mask removal process may be different from the etching solution used to remove a region of the mask member PR that has reacted in the exposure process.

Referring to FIG. 18F, a solder pattern SDP may be arranged on the first electrode CE1 through the second hole H2 of the passivation layer 116.

Referring to FIG. 18G, a light-emitting element ED may be arranged on the solder pattern SDP. At this time, the first electrode CE1 and the light-emitting element ED may be electrically connected through eutectic bonding using the solder pattern SDP.

Referring to FIG. 18H, a first optical layer 117a may be arranged to surround the light-emitting element ED in the display area AA. The first optical layer 117a may cover the bank BNK, a portion of the passivation layer 116, and a side surface of the light-emitting element ED.

Referring to FIG. 18I, the second optical layer 117b may be arranged to surround the first optical layer 117a. At this time, a contact hole CTH may be formed in the second optical layer 117b by using an exposure process and an etching process, and the contact hole CTH may overlap with the first hole H1 of the passivation layer 116. As a result, a portion of the upper surface of the contact electrode CCE may be exposed. Here, the second optical layer 117b may cover a portion of the passivation layer 116.

Referring to FIG. 18J, the second electrode CE2 may be arranged on the light-emitting element ED, the first optical layer 117a, the second optical layer 117b, and the contact electrode CCE. The second electrode CE2 may be arranged on the contact electrode CCE through the contact hole CTH formed in the second optical layer 117b. Hence, the second electrode CE2 may be electrically connected to the light-emitting element ED and the contact electrode CCE. In this case, the passivation layer 116 may be arranged between the contact electrode CCE and the second optical layer 117b to thereby preventing or reducing delamination that may occur in a region where the inner end of the second optical layer 117b and the contact electrode CCE meet.

FIG. 19 is a cross-sectional view of a display device according to another embodiment of the present specification. For example, FIG. 19 is a cross-sectional view illustrating a protrusion P projecting in the Z-axis direction from the third insulating layer 115c, and a contact electrode CCE arranged on the protrusion P. In addition, the display panel 100 illustrated in FIG. 9 may represent a display panel according to the first embodiment, and the display panel 100 illustrated in FIG. 19 may represent a display panel according to the second embodiment.

When comparing the display panel according to the first embodiment with the display panel according to the second embodiment with reference to FIGS. 9 and 19, the display panel according to the second embodiment may be different from the display panel according to the first embodiment in that it includes a protrusion P projecting in the Z-axis direction from the third insulating layer 115c and that the contact electrode CCE is arranged on the protrusion P. Thereby, the protrusion P may reduce penetration of moisture or impurities by acting as a protective barrier that increases the penetration path of moisture or impurities. Additionally, the protrusion P may guide the placement position of the contact electrode CCE according to the protruding shape.

When describing the display panel according to the second embodiment with reference to FIGS. 1 to 8, 9 and 19, as the same components of the display panel according to the first embodiment and the display panel according to the second embodiment may be indicated by the same reference symbols, a detailed description thereof will be omitted.

The display device 1000 according to an embodiment of the present specification may include a display panel 100 according to the second embodiment, a polarizing layer 293, an adhesive layer 295, a cover 120, a substrate 110, a flexible circuit board CB, and a printed circuit board 160.

The display panel 100 according to the second embodiment may include a first buffer layer 111a, a second buffer layer 111b, an adhesive layer 112, a pixel driving circuit PD, a first protective layer 113a, a second protective layer 113b, a third protective layer 114, a first insulating layer 115a, a second insulating layer 115b, a third insulating layer 115c, a passivation layer 116, a plurality of first connection lines 121, a plurality of second connection lines 122, a plurality of signal lines TL, a plurality of communication lines NL, a plurality of first electrodes CE1, a plurality of banks BNK, a plurality of light-emitting elements ED, a plurality of second electrodes CE2, a plurality of solder patterns SDPb, a plurality of contact electrodes CCE, a first optical layer 117a, a second optical layer 117b, a third optical layer 117c, and a black matrix BM, which are arranged on the substrate 110, and may further include a protrusion P projecting from the third insulating layer 115c.

Referring to FIG. 19, the protrusion P may project from the third insulating layer 115c, extend in the Z-axis direction, and overlap with the contact electrode CCE in the Z-axis direction. For example, the contact electrode CCE may be arranged on the protrusion P.

The protrusion P may be formed in a trapezoidal shape where the upper surface is smaller than the lower surface, and the contact electrode CCE of a trapezoidal shape may be arranged on the upper surface of the protrusion P. Here, the area of the upper surface of the protrusion P may be equal to the area of the lower surface BSCCE of the contact electrode CCE, without being limited thereto.

When the contact electrode CCE arranged on the third insulating layer 115c is processed into a trapezoidal shape through an etching process, a portion of the upper surface of the third insulating layer 115c may be removed to form the protrusion P. Consequently, when the passivation layer 116 is deposited, the contact area between the third insulating layer 115c made of an organic insulating material and the passivation layer 116 increases, so that the adhesive strength between the third insulating layer 115c and the passivation layer 116 may also be improved. In addition, since the residual film around the contact electrode CCE is removed together with a portion of the upper surface of the third insulating layer 115c, it is possible to prevent or reduce the contact electrode CCE from being short-circuited with other wiring lines arranged on the third insulating layer 115c due to the residual film of the contact electrode CCE.

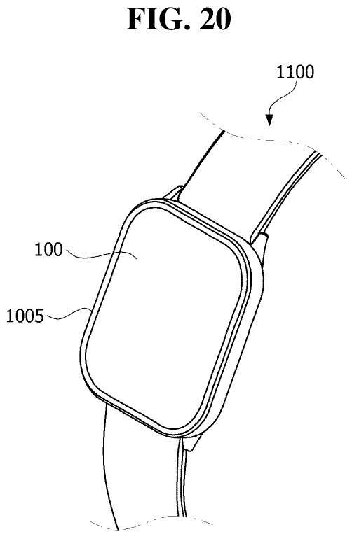

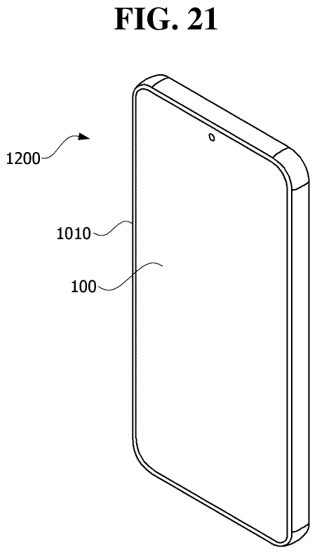

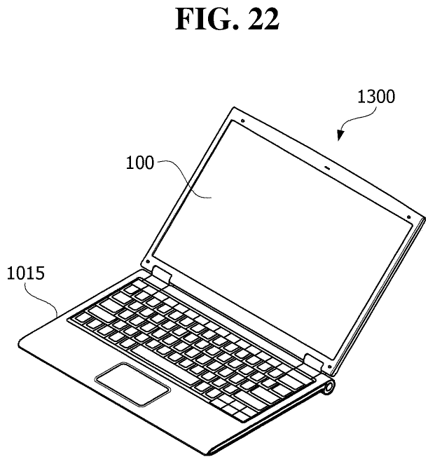

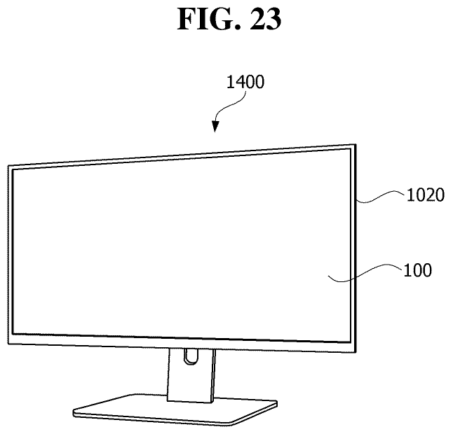

FIGS. 20 to 23 are diagrams illustrating devices to which the display device according to embodiments of the present specification is applied.

Referring to FIGS. 20 to 23, the display device 1000 according to embodiments of the present specification may be included in various devices or electronic devices. For example, as illustrated in FIGS. 20 to 23, various electronic devices may include a wearable device 1100, a mobile device 1200, a laptop 1300, and a monitor or TV 1400, but the embodiments of the present specification are not limited thereto.

Each of the wearable device 1100, the mobile device 1200, the laptop 1300, and the monitor or TV 1400 may respectively include a casing 1005, 1010, 1015, or 1020, and the display panel 100, 100a, 100b, 100c, 100d, or 100e and the display device 1000 according to embodiments of the present specification as described in FIGS. 1 to 19.

For example, the display device according to the embodiment of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical device, a desktop PC, a laptop PC, a netbook computer, a workstation, a navigation device, a vehicle display device, a theater display device, a television, a wallpaper device, a signage device, a game device, a laptop computer, a monitor, a camera, a camcorder, a home appliance, and the like.

A display panel according to one or more embodiments of the present specification and a display device including the same may be described as follows.

The display panel according to one or more embodiments of the present specification may include: an insulating layer arranged on a substrate; a bank and a contact electrode arranged to be spaced apart from each other on the insulating layer; a first electrode arranged on the bank; a passivation layer including a first hole exposing an upper surface of the contact electrode and a second hole exposing an upper surface of the first electrode; a light-emitting element arranged on the first electrode; a second electrode arranged on the light-emitting element; a first optical layer surrounding the light-emitting element; and a second optical layer arranged on the side of the first optical layer, wherein the second electrode may come into contact with the upper surface of the contact electrode through a contact hole formed in the second optical layer and the first hole of the passivation layer.

According to an embodiment of the present specification, the second optical layer may be made of an organic insulating material, and the passivation layer may be made of an inorganic insulating material.

According to an embodiment of the present specification, the passivation layer may include a first passivation region in contact with the upper surface of the contact electrode, a second passivation region extending from the first passivation region and in contact with the side surface of the contact electrode, and a third passivation region extending from the second passivation region and arranged on the insulating layer, wherein the second optical layer may be arranged on the third passivation region.

According to an embodiment of the present specification, the first passivation region may include an inner region and an outer region, wherein the second electrode may be arranged in the inner region, and the second optical layer may be arranged in the outer region.

According to an embodiment of the present specification, with respect to the center of the contact electrode, a first inner end of the passivation layer forming the first hole may be located at a first distance, the side surface of the second optical layer forming the contact hole may be located at a second distance, and the side edge of the contact electrode may be located at a third distance, wherein the second distance may be greater than the first distance and less than the third distance.

According to an embodiment of the present specification, the insulating layer may further include a protrusion, and the contact electrode may be arranged on the protrusion.

According to an embodiment of the present specification, the insulating layer may be made of an organic insulating material.

According to an embodiment of the present specification, the contact electrode may include a first conductive layer, a second conductive layer arranged on the first conductive layer, a third conductive layer arranged on the second conductive layer, and a fourth conductive layer arranged on the third conductive layer, wherein the second conductive layer may include aluminum.

According to an embodiment of the present specification, the thickness of the second conductive layer may be greater than the thickness of the first conductive layer.

According to an embodiment of the present specification, the second electrode may cover the first inner end of the passivation layer forming the first hole.

According to an embodiment of the present specification, the contact electrode and the first electrode may include a plurality of identical conductive layers.

According to an embodiment of the present specification, the display panel may include a signal line arranged between adjacent banks, and the signal line may include the same metal layer as the first electrode.

According to an embodiment of the present specification, the display panel may include a pixel driving circuit arranged on the substrate, and a plurality of connection lines electrically connecting the first electrode and the pixel driving circuit.

According to an embodiment of the present specification, the light-emitting element may be a micro LED.

According to an embodiment of the present specification, the light-emitting element may have a vertical structure.

According to an embodiment of the present specification, the display panel may further include a solder pattern arranged in the second hole, and the first electrode and the light-emitting element may be electrically connected through eutectic bonding using the solder pattern.

A display device according to one or more embodiments of the present disclosure may include: a display panel; a polarizing layer arranged on the display panel; a printed circuit board; and a flexible circuit board electrically connecting the display panel and the printed circuit board, wherein the display panel may include an insulating layer arranged on a substrate, a bank and a contact electrode arranged to be spaced apart from each other on the insulating layer, a first electrode arranged on the bank, a passivation layer including a first hole exposing an upper surface of the contact electrode and a second hole exposing an upper surface of the first electrode, a light-emitting element arranged on the first electrode, a second electrode arranged on the light-emitting element, a first optical layer surrounding the light-emitting element, and a second optical layer arranged on the side of the first optical layer, wherein the second electrode may come into contact with the upper surface of the contact electrode through a contact hole formed in the second optical layer and the first hole of the passivation layer.

According to an embodiment of the present specification, with respect to the center of the contact electrode, a first inner end of the passivation layer forming the first hole may be located at a first distance, the side surface of the second optical layer forming the contact hole may be located at a second distance, and the side edge of the contact electrode may be located at a third distance, wherein the second distance may be greater than the first distance and less than the third distance.

According to an embodiment of the present specification, the insulating layer may further include a protrusion, and the contact electrode may be arranged on the protrusion.

According to an embodiment of the present specification, the second electrode may cover the first inner end of the passivation layer forming the first hole.

According to an embodiment of the present specification, the contact electrode and the first electrode may include a plurality of identical conductive layers.

The objects to be achieved by the present disclosure, the means for achieving the objects, and effects of the present disclosure described above do not specify essential features of the claims, and thus, the scope of the claims is not limited to the disclosure of the present disclosure.

Although the embodiments of the present disclosure have been described in more detail with reference to the accompanying drawings, the present disclosure is not limited thereto and may be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure.

### LIST OF REFERENCE NUMBERS

| | |
|---|---|
| 100: Display panel | 110: Substrate |
| 116: Passivation layer | 120: Cover |
| 121: First connection line | 122: Second connection |
| 130: First light-emitting element | 140: Second light-emitting element |
| 150: Third light-emitting element | 160: Printed circuit board |
| 170a: First optical layer | 170b: Second optical layer |
| 293: Polarizing layer | 295: Adhesive layer |
| 1005, 1010, 1015, 1020: Case | |
| AA: Display area | BA: Bending area |
| BM: Black matrix | BNK: Bank |
| CB: Flexible circuit board | CCE: Contact electrode |
| CE1: First electrode | CE2: Second electrode |
| CTH: Contact hole | ED: Light-emitting element |
| H1: First hole | H2: Second hole |
| SDP: Solder pattern | SP1: First sub-pixel |
| SP2: Second sub-pixel | SP3: Third sub-pixel |
| TL: Signal line | |

What is claimed is:

1. A display panel comprising:
an insulating layer on a substrate;
a bank and a contact electrode that are spaced apart from each other on the insulating layer;
a first electrode on the bank;
a passivation layer including a first hole exposing an upper surface of the contact electrode and a second hole exposing an upper surface of the first electrode;
a light-emitting element on the first electrode;
a second electrode on the light-emitting element;
a first optical layer surrounding the light-emitting element; and
a second optical layer on a side of the first optical layer,
wherein the second electrode is in contact with the upper surface of the contact electrode through a contact hole formed in the second optical layer and the first hole of the passivation layer.

2. The display panel of claim 1, wherein the second optical layer includes an organic insulating material and the passivation layer includes an inorganic insulating material.

3. The display panel of claim 1, wherein the passivation layer includes a first passivation region in contact with the upper surface of the contact electrode, a second passivation region extending from the first passivation region and in contact with a side surface of the contact electrode, and a third passivation region extending from the second passivation region and arranged on the insulating layer; and
the second optical layer is on the third passivation region.

4. The display panel of claim 3, wherein the first passivation region includes an inner region and an outer region, the second electrode is in the inner region, and the second optical layer is in the outer region.

5. The display panel of claim 1, wherein with respect to a center of the contact electrode, a first inner end of the passivation layer forming the first hole is located at a first distance, a side surface of the second optical layer forming the contact hole is located at a second distance, and a side edge of the contact electrode is located at a third distance; and
the second distance is greater than the first distance and less than the third distance.

6. The display panel of claim 1, wherein the insulating layer further includes a protrusion and the contact electrode is on the protrusion.

7. The display panel of claim 6, wherein the insulating layer includes an organic insulating material.

8. The display panel of claim 1, wherein the contact electrode includes a first conductive layer, a second conductive layer on the first conductive layer, a third conductive layer on the second conductive layer, and a fourth conductive layer on the third conductive layer; and
the second conductive layer includes aluminum.

9. The display panel of claim 8, wherein a thickness of the second conductive layer is greater than a thickness of the first conductive layer.

10. The display panel of claim 1, wherein the second electrode covers a first inner end of the passivation layer forming the first hole.

11. The display panel of claim 1, wherein the contact electrode and the first electrode include a plurality of identical conductive layers.

12. The display panel of claim 1, further comprising:
a signal line between adjacent banks, the signal line including a same metal layer as the first electrode.

13. The display panel of claim 1, further comprising:
a pixel driving circuit on the substrate; and
a plurality of connection lines electrically connecting the first electrode and the pixel driving circuit.

14. The display panel of claim 1, wherein the light-emitting element is a micro light-emitting diode.

15. The display panel of claim 1, wherein the light-emitting element has a vertical structure.

16. The display panel of claim 1, further comprising:
a solder pattern in the second hole,
wherein the first electrode and the light-emitting element are electrically connected using the solder pattern.

17. A display device comprising:
a display panel;
a polarizing layer on the display panel;
a printed circuit board; and
a flexible circuit board electrically connecting the display panel and the printed circuit board,
wherein the display panel includes an insulating layer on a substrate, a bank and a contact electrode that are spaced apart from each other on the insulating layer, a first electrode on the bank, a passivation layer including a first hole exposing an upper surface of the contact electrode and a second hole exposing an upper surface of the first electrode, a light-emitting element on the first electrode, a second electrode on the light-emitting element, a first optical layer surrounding the light-emitting element, and a second optical layer on a side of the first optical layer, and
wherein the second electrode is in contact with the upper surface of the contact electrode through a contact hole formed in the second optical layer and the first hole of the passivation layer.

18. The display device of claim 17, wherein with respect to a center of the contact electrode, a first inner end of the passivation layer forming the first hole is located at a first distance, a side surface of the second optical layer forming the contact hole is located at a second distance, and a side edge of the contact electrode is located at a third distance; and
the second distance is greater than the first distance and less than the third distance.

19. The display device of claim 17, wherein the insulating layer further includes a protrusion and the contact electrode is on the protrusion.

20. The display device of claim 17, wherein the second electrode covers a first inner end of the passivation layer forming the first hole.
